(19) United States
(12) Patent Application Publication
(10) Pub. No.: US 2025/0304449 A1
(43) Pub. Date: Oct. 2, 2025

(54) METHOD FOR PREPARING TRANSPARENT CONDUCTIVE FILMS

(71) Applicant: INSTITUTE OF PHYSICS, CHINESE ACADEMY OF SCIENCES, Beijing (CN)

(72) Inventors: Weiya ZHOU, Beijing (CN); Ying YUE, Beijing (CN); Di ZHANG, Beijing (CN); Yanchun WANG, Beijing (CN)

(21) Appl. No.: 19/092,259

(22) Filed: Mar. 27, 2025

(30) Foreign Application Priority Data
Mar. 28, 2024 (CN) 202410369168.3

(51) Int. Cl. C01B 32/168

(52) U.S. Cl. CPC C01B 32/168; C01B 2202/08; C01B 2202/22; C01B 2202/26; C01P 2002/85; C01P 2004/03; C01P 2004/04

(57) ABSTRACT

Provided is a method for preparing transparent conductive films (TCFs), including: laying at least one original carbon nanotube (CNT) film on a surface of a substrate and placing them into a growth chamber; enabling the surface of the substrate to undergo reconstruction resulted from an interaction with a gas in the growth chamber, accompanied by transport of atoms constituting facets, to form facets, which appear as a regular stepped or zigzag pattern at a mesoscopic scale on the surface of the substrate; making the facets interact with the original CNT film, to remove impurities, and to cause at least a portion of CNTs in the original CNT film to move under driving of the facets, thereby compelling adjacent CNTs or bundles to adhere closely together, resulting in reorganization of a CNT network in the original CNT film to form a whole reorganized CNT TCF.

### CROSS-REFERENCE TO RELATED APPLICATIONS

The present application claims priority to Chinese patent application No. 202410369168.3 entitled “Method for preparing transparent conductive films”, filed on Mar. 28, 2024, the entire contents of which are incorporated herein by reference.

### TECHNICAL FIELD

The present application relates to the field of materials technology, and in particular, to a method for preparing transparent conductive films.

### BACKGROUND

In the present world, the application of transparent conductors has become increasingly prevalent. Transparent conductive films (TCFs) are extensively employed in modern electronic devices. Currently, indium tin oxide (ITO) remains the predominant material for manufacturing TCFs due to its superior transparent conductivity. Over nearly a century of research and development, ITO has established a comprehensive industrial ecosystem. However, since indium is a non-renewable resource, the escalating demand has led to a sharp increase in the cost of ITO in recent years. Moreover, the inherent brittleness and high areal density of ITO pose significant challenges for its application in the rapidly evolving domains of flexible wearable devices and aerospace. In addition, ITO is typically prepared on a substrate through methods such as magnetron sputtering, which precludes it from being free-standing and thereby restricts its utility in advanced applications like radiative heat and light detectors and thermoacoustic speakers. Moreover, the preparation area is limited by the size of the target material. These challenges position large-area TCFs preparation for high-end products as one of the critical ‘bottleneck’ techniques.

Driven by advancements in next-generation flexible electronics/devices, flexible optoelectronics/devices, and wearable devices/systems, TCFs are faced with increasingly stringent requirements in performance, specifically for integration of excellent transparent conductivity, mechanical flexibility, high strength and even free-standing capability, concurrent with the capacity for large-area and large-scale preparation. Carbon nanofilms have previously been considered as the most competitive ideal material to replace ITO TCFs widely used in industry. If the challenge can be indeed addressed to achieve the preparation of nano carbon TCFs in line with the industrial standard mentioned above, it can undoubtedly provide an effective solution to this critical ‘bottleneck’ problem of the key technical issues of large-area TCFs. Therefore, the development of a large-area flexible TCF and its preparation method to meet the requirements of future electronic devices for TCFs, that is, simultaneously endowing TCFs with lightweight, high strength, flexibility, excellent transmittance and conductivity characteristics, meanwhile enabling large-area production, holds important scientific and application value for large-area flexible TCFs, allowing the as-prepared TCF to be directly transferred at room temperature without the need for high temperature sputtering typically required for ITO.

### SUMMARY

In light of the aforementioned challenges, this invention presents a method for preparing TCFs aimed at addressing or at least partially resolve these issues.

One object of the present invention is to achieve large-area preparation of TCF.

A further object of the present invention is to improve the performance of TCF.

A further object of the present invention is to integrate graphene into TCF to obtain a hybrid graphene-reorganized CNT transparent conductive film (G-RCNT TCF), thereby greatly improving the performance of TCF.

Particularly, the present invention provides a method for preparing TCF, comprising:
laying an original carbon nanotube (CNT) film with a predetermined area on a surface of a substrate and placing them into a growth chamber;
enabling the substrate to undergo surface reconstruction with a gas in the growth chamber, accompanied by transport of atoms constituting facets, to form the said facets, the facets being manifested as a regular stepped or zigzag pattern at a mesoscopic scale on the surface of the substrate; and
making the facets interact with the original CNT film, to remove impurities from the original CNT film, and to cause at least a portion of the CNTs in the original CNT film to move under driving of the facets, thereby compelling adjacent CNTs or bundles to adhere closely together, resulting in reorganization of a CNT network in the original CNT film to form a whole reorganized CNT transparent conductive film (RCNT-TCF).

Optionally, a step of enabling the substrate to undergo surface reconstruction with a gas in the growth chamber to form the facets includes:
purging the growth chamber to control a partial pressure of the gas in the growth chamber that interacts with the substrate to initiate the surface reconstruction to be within a set range; and
heating the growth chamber to control the surface reconstruction that occurs under interactions of the gas and the substrate, thereby forming the facets.

Optionally, the gas described is a gas, in the growth chamber, that is capable of interacting with the substrate to initiate surface reconstruction, and includes any one or a mixture of oxidizing gases, or any one or a mixture of reducing gases;
a source of the gas includes any one of forms of gas, liquid, and solid, or any combination of the above multiple forms.

Optionally, making the facets interact with the original CNT film includes:
continuing heating the growth chamber to promote gradual growth of the facets on the substrate, thereby facilitating gradual tight adhesion of the CNT network to the facets and gradual elimination of impurities in the original CNT film; and
the CNTs in the original CNT network moving and approaching each other as the facets grow up, leading to their reorganization into a Y-type interconnected network with a long common segment to form a new reorganized CNT network, thereby obtaining the RCNT-TCF.

Optionally, after making the facets interact with the original CNT film, the method further comprises: introducing a carbon source and an auxiliary gas into the growth chamber to grow graphene, thereby obtaining a G-RCNT TCF.

Optionally, after making the facets interact with the original CNT film, the method further comprises:
cooling the RCNT-TCF at a preset cooling rate; and
etching the substrate off the cooled RCNT-TCF using a substrate etchant, allowing the RCNT-TCF to float on a surface of the substrate etchant, and washing the RCNT-TCF with a rinsing solution.

Optionally, after introducing a carbon source and an auxiliary gas into the growth chamber to grow graphene, the method further comprises:
cooling the G-RCNT TCF at a preset cooling rate; and
etching the substrate off the cooled G-RCNT TCF using a substrate etchant, allowing the G-RCNT TCF to float on a surface of the substrate etchant, and washing the G-RCNT TCF with a rinsing solution.

Optionally, laying the original CNT film with a predetermined area on the surface of the substrate includes:
splicing multiple pieces of the original CNT films and laying them on the surface of the substrate to ensure the surface of the substrate is completely bespread with the original CNT films, with at least one layer of the original CNT films covering the surface of the substrate.

Optionally, after laying the original CNT film with a predetermined area on the surface of the substrate, the method further comprises:
dripping a volatile organic solvent onto the original CNT film to infiltrate the original CNT film to increase contact between the original CNT film and the surface of the substrate;
and

after the organic solvent is completely evaporated, placing the original CNT film on the substrate into the growth chamber.

Optionally, the CNTs in the original CNT film include at least one type or a combination of multiple types of the following: single-walled CNTs, double-walled CNTs, few-walled CNTs, and multi-walled CNTs.

Optionally, a thickness of the original CNT film is greater than 0.1 nm.

The preparation method of TCF in the present invention involves laying an original CNT film with a predetermined area on a surface of a substrate, followed by placing them into a growth chamber. Subsequently, surface reconstruction is initiated on the surface of the substrate through its interaction with the gas, resulting in the formation of facets. This process is accompanied by the transport of a large number of atoms or molecules constituting the facets, which evolve from nothing to gradually enlarge, manifesting as a regular stepped or zigzag pattern on the surface of the substrate at a microscopic or mesoscopic scale. Concurrently, the facets interact with the original CNT film. Under certain conditions (temperature, atmosphere, etc.), as the facets on the substrate gradually grow up, the transport of a large number of atoms or molecules constituting the facets drives movement of CNTs including impurities (referred to as driving of the facets), which causes a CNT network in the original CNT film to gradually adhere to the facets and the impurities to gradually dissolve, thereby removing impurities from the original CNT film. Meanwhile, at least part of the CNTs in the original film relocate under driving of the facets, reorganizing the CNT network into RCNT-TCF. Within a certain temperature range, these interactions may occur and proceed separately one or more at a time, or simultaneously, or in an interwoven manner.

The original CNT film generally contains impurities if it is unpurified or is incompletely purified. These impurities vary in type and include defective CNTs, weak CNTs, catalyst particles, and amorphous carbon. Due to the diverse nature of different impurities, the conditions under which facets interact with these impurities exhibit variability. On the facets, intense atomic migration and transport lead to the rapid dissociation of impurities such as dispersants and organic substances into smaller units like gases, water, inorganic compounds, or amorphous carbon at certain temperatures, i.e., decomposition. On the other hand, impurities including metals, inorganic salts, amorphous carbon, catalyst particles, defective or weak CNTs tend to rapidly integrate into the facets through processes such as alloying, diffusion, and solid solution formation under driving of the facets, i.e., dissolution. Generally, the lowest temperature at which the facets interact with any given impurity is denoted as T_{L}.

Under an applicable atmosphere for facet formation through surface reconstruction with the substrate in a certain temperature range, the aforementioned interactions may occur singly, or simultaneously, or in an interwoven manner. The sequence of occurrence of these processes is influenced by driving of the facets, which manifests in the various stages from the formation to expansion of the facets, as well as their different processes of interactions with the original CNT film (which contains impurities), all of which are related to the intrinsic properties of the facets, impurities, and CNTs. The following is a comprehensive explanation:

(1) When temperature Tₓ reaches T₁ (a temperature at which the selected substrate begins to exhibit facets), the facets begin to appear on the substrate. The temperature range for forming facets is configured as Tₓ≥T₁. When Tₓ=T₁, the interaction between the facets and the original CNT film begins but is not conspicuous. When Tₓ≥T_{L}, some interactions between the facets and impurities become gradually evident, while others have yet to occur. Therefore, when Tₓ=T₁, the reorganization process is not obvious or incomplete.

As the temperature continues to increase, i.e., Tₓ>T₁, the facets begin to grow up gradually, meanwhile their boundaries start to expand and lead to the gradual convergence of boundaries between some or most adjacent facets, resulting in the formation of distinct stepped or zigzag morphologies on the substrate. During the gradual growth of the facets, accompanied by the transport of a large number of atoms or molecules constituting the facets, the interaction between the facets and the original CNT film becomes apparent: at least part of the CNTs in the original CNT film gradually adhere to the facets under driving of the facets, compelling some CNTs to converge at the contact areas between facets, resulting in the formation of dense bundles of neighboring CNTs, thereby reorganizing part of the original CNT network into a new Y-type interconnected network with a long common segment. Simultaneously, when Tₓ≥T_{L}, the facets gradually eliminate at least one type of impurity in the original CNT film. When Tₓ>>T₁, the reorganization process becomes increasingly evident, manifested as follows: portions of the CNTs in the original CNT film continuously adhere to the facets under driving of the facets, followed by movement and reorganization of the network in the original CNT film. The facets continuously dissolve part or most of the impurities (including defective CNTs, weak CNTs, catalyst particles, and amorphous carbon) in the tightly adhered film, reorganizing CNTs into part of a new Y-type interconnected network with a long common segment.

(2) When the temperature Tₓ rises from T₁ to T₂ (the temperature at which the facets begin to grow up conspicuously and form regular stepped or zigzag facets), the facets grow up from gradually to rapidly, their edges expand and contact each other. As the contact areas continue to expand, grooves and depressions form between the facets, ultimately forming regular and orderly stepped or zigzag morphologies. During this process, the interaction between the facets and the CNT film (containing impurities) becomes conspicuous. Therefore, at Tₓ=T₂, it is essential to maintain the temperature for a certain duration to ensure that the facet growth process has adequate time to proceed, meanwhile allowing the conspicuous interactions to persist for a sufficient period, thereby ensuring their completion to a greater extent. The reorganization process becomes conspicuous, manifested as follows: Under driving of the facets, more CNTs in the original CNT film adhere to the facets, followed by noticeable movement, with most CNTs compelled to converge at the grooves between facets and the depressions formed at the edges of the facets. Neighboring CNTs in the original network approach each other and reorganize into a new Y-type interconnected network with a long common segment composed of CNT bundles constrained by van der Waals forces. During the process where CNTs in the CNT network converge as the facets grow up, due to the removal of weak CNTs and bundles in the original network, the pore diameters (also called pore sizes) in the reorganized network change—except for a few pores whose diameters remain unchanged, most slightly increase or decrease. The reorganized network is also constrained by the original network, and the pore diameters formed by reorganization generally do not exceed the larger pores in the original network. Hence, under the dual effect of driving of the facets and original network constraints, the network structure of RCNT-TCF is optimized, resulting in more uniform pore diameters and decreased film areal density. Generally, T₂>T_{L}, and maintaining the temperature at Tₓ=T₂ for a certain period allows the facets to continuously dissolve impurities (these impurities include catalyst particles, amorphous carbon, defects, and weak CNTs, which quickly fuse with the facets through alloying, diffusion, and solid solution formation, i.e., dissolution), removing most or almost all impurities, thereby forming a larger-area continuous Y-type interconnected network with a long common segment by reorganization, and further reducing the film areal density. Through conspicuous reorganization maintained at Tₓ=T₂ for a certain period, the entire original CNT network film is basically transformed through the interaction of the facets with the CNTs and impurities, forming a new, whole and large-area Y-type interconnected network with a long common segment, completing the reorganization of the original CNT film. Hence, under the dual effect of driving of the facets and original network constraints, the roughness of the RCNT network film decreases, the pore diameters become more uniform, and the film areal density decreases.

(3) The step of the facets interacting with the original CNT film also includes: when the temperature Tₓ rises from T₂ to T₃ (the temperature at which the selected surface of the substrate begins to melt), the morphological characteristics of the facets start to disappear. When Tₓ>T₃, which marks the temperature range wherein the morphological characteristics of the facets progressively diminish, the CNT network reorganization process is completed. Since T₃ approaches or reaches the melting point of the substrate, the pre-melting of the surface of the substrate becomes more conspicuous, and the morphological characteristics of the facets basically disappear, completing the reorganization process while preserving the structure of the newly formed a large-area Y-type interconnected network with a long common segment. As the facets gradually disappear, almost all or all impurities are removed, obtaining a clean, continuous RCNT network film on the surface of the substrate. Hence, under the dual effect of driving of the facets and original network constraints, the network structure of RCNT-TCF is further optimized, and compared with the original CNT film, the reorganized network film exhibits reduced roughness, more uniform pore diameters, and decreased film areal density.

The situation in which the original CNT film is placed on the surface of the substrate exhibits regional variations at both microscopic and mesoscopic scales, leading to differing interaction processes. Consequently, the aforementioned three steps may occur separately, concurrently, or in an intertwined manner under specific conditions during the entire interaction process between the facet and the original CNT film.

Through this method, the resultant RCNT-TCF exhibits improved performance as a TCF by forming a more efficient internal conductive network with a more uniform continuous network structure and reduced areal density. Furthermore, the method of the present invention can achieve large-area preparation of TCFs while enabling the free-standing capability of such large-area TCFs.

Furthermore, in the preparation method of TCF in the present invention, after enabling the facets to interact with the original CNT film, carbon sources and auxiliary gases are introduced into the growth chamber to grow graphene, obtaining G-RCNT TCF. Through this method, graphene can fill the pores in the CNT network of RCNT-TCF, obtaining G-RCNT TCF. Such a structure combines the advantages of graphene and CNTs, greatly enhancing the performance of TCF. Additionally, the method of the present invention can achieve large-area preparation of G-RCNT TCFs and enable the free-standing capability of such large-area TCFs.

Based on the detailed description of specific embodiments of the present invention combined with the accompanying drawings below, those skilled in the art will better understand the aforementioned and other purposes, advantages, and features of the present invention.

### BRIEF DESCRIPTION OF DRAWINGS

Some specific embodiments of the present invention will be described in detail later in an exemplary and not limiting manner with reference to the accompanying drawings. Identical attachment marks in the accompanying drawings identify the same or similar components or parts. It should be understood by those skilled in the art that these accompanying drawings are not necessarily drawn to scale. In the accompanying drawings:

FIG. 1 is a flowchart of a method for preparing a TCF according to an embodiment of the present invention;

FIG. 2 is a flowchart of a method for preparing a TCF according to another embodiment of the present invention;

FIG. 3 is a flowchart of a method for preparing a TCF according to yet another embodiment of the present invention;

FIG. 4 is a schematic diagram of a pattern of facets on a surface of a substrate, from a method for preparing a TCF according to an embodiment of the present invention;

FIG. 5A is a schematic diagram of an original CNT film on a surface of a substrate before reorganization of a CNT network under driving of the facets to form a TCF according to an embodiment of the method of the present invention;

FIG. 5B is a schematic diagram of a reorganization process of a CNT network by driving of the facets on the surface of the substrate to form a whole TCF according to an embodiment of the method of the present invention;

FIG. 6A is a schematic diagram of spliced multilayer CNT networks on a surface of a substrate before reconfiguration under driving of the facets according to an embodiment of the present invention;

FIG. 6B is a schematic diagram of a reorganization process of splicing multilayer CNT networks by driving of the facets on the surface of the substrate to form a whole TCF according to an embodiment of the present invention;

FIG. 7 shows mechanical strength test results of an original CNT film, RCNT-TCF and G-RCNT TCF in an embodiment of the present invention;

FIG. 8A is a typical high-resolution transmission electron microscopy (HRTEM) image of an original CNT film with a scale bar of 500 nm according to an embodiment of the method for preparing a TCF of the present invention;

FIG. 8B is a typical HRTEM image of an original CNT film with a scale bar of 50 nm, according to an embodiment of the method for preparing a TCF of the present invention;

FIG. 8C is a typical HRTEM image of an original CNT film with a scale bar of 10 nm, according to an embodiment of the method for preparing a TCF of the present invention;

FIG. 8D shows a result of an original CNT film characterized by energy dispersive spectroscopy (EDS), obtained in an embodiment of the method for preparing a TCF of the present invention;

FIG. 9A is a typical HRTEM image of an RCNT with a scale bar of 500 nm according to a method for preparing a TCF in an embodiment of the present invention;

FIG. 9B is a typical HRTEM image of an RCNT with a scale bar of 50 nm according to a method for preparing a TCF in an embodiment of the present invention;

FIG. 9C shows a result of an RCNT-TCF characterized by EDS, obtained in an embodiment of the method for preparing a TCF of the present invention;

FIG. 10 is a scanning electron microscope (SEM) image of facets on a surface of copper according to an embodiment of a method for preparing a TCF of the present invention;

FIG. 11A is an SEM image of an original CNT film on a surface of a copper foil according to an embodiment of a method for preparing a TCF of the present invention;

FIG. 11B is an SEM image of an RCNT-TCF with a copper foil according to a method of preparing a TCF of one embodiment of the present invention;

FIG. 12A is an SEM image of an original spliced CNT film on a surface of a copper foil according to an embodiment of the method for preparing a TCF of the present invention;

FIG. 12B is an SEM image of an RCNT-TCF with a copper foil according to an embodiment of the method for preparing a TCF of the present invention;

FIG. 13A is an SEM image of an original 2-layer CNT film on a surface of a copper foil according to an embodiment of the method for preparing a TCF of the present invention;

FIG. 13B is an SEM image of an RCNT-TCF with a copper foil through reorganization process of an original 2-layer CNT film by driving of the facets according to an embodiment of the method for preparing a TCF of the present invention;

FIG. 14A is an SEM image of an original CNT film according to an embodiment of the method for preparing a TCF of the present invention;

FIG. 14B is an SEM image of a G-RCNT TCF according to an embodiment of the method for preparing a TCF of the present invention;

FIG. 15A is an atomic force microscope (AFM) image of an original CNT film according to an embodiment of the method for preparing a TCF of the present invention;

FIG. 15B is an AFM image of a G-RCNT TCF according to an embodiment of the method for preparing a TCF of the present invention;

FIG. 15C is a cross-sectional analysis view of an AFM image of an original CNT film according to an embodiment of the method for preparing a TCF of the present invention;

FIG. 15D is a cross-sectional analysis view of an AFM image of a G-RCNT TCF according to an embodiment of the method for preparing a TCF of the present invention;

FIG. 16 shows a testing graph of transparent conductivity of various TCFs according to an embodiment of the method for preparing a TCF of the present invention;

FIG. 17 is an SEM image of a G-RCNT TCF according to an embodiment of the method for preparing a TCF of the present invention;

FIG. 18 shows an optical image of a free-standing large-area RCNT-TCF floating on a surface of deionized water according to an embodiment of the method for preparing a TCF of the present invention;

FIG. 19 shows an optical image of a free-standing large-area G-RCNT TCF in air according to an embodiment of the method for preparing a TCF of the method for preparing a TCF of the present invention;

FIG. 20 shows an optical image of a free-standing large-area G-RCNT TCF floating on a surface of substrate etchant liquid according to an embodiment of the method for preparing a TCF of the present invention; and

FIG. 21 shows an optical image of a free-standing large-area G-RCNT TCF floating on a surface of deionized water according to another embodiment of the method for preparing a TCF of the present invention.

### DETAILED DESCRIPTION OF THE EMBODIMENTS

Those skilled in the art in this field should understand that the embodiments described below are only part of the embodiments of the present invention, rather than all embodiments. These partial embodiments are intended to illustrate the technical principles of the present invention rather than to limit the scope of protection thereof. Based on the embodiments disclosed herein, any other embodiments derived by those of ordinary skill in the art without making creative efforts should be encompassed within the scope of protection of the present invention.

Currently, developing new TCFs to replace ITO films has remained a key objective for researchers in this field. The industry generally agrees that TCFs applied in smart windows, displays, touch screens, wearable products, etc., should maintain a transmittance of over 85%. Moreover, for most electronic devices (such as touch screens), the sheet resistance is required to be below 300 Ω/sq, while for others (such as liquid crystal displays), the sheet resistance is even required to be below 100 Ω/sq. In particular, future displays need flexible transparent electrodes that can be manufactured over large areas at low temperatures and low costs. To date, neither ITO-based TCFs nor current potential alternatives (such as alternative metal oxides, metal films, or metal grids) can fully meet these requirements. However, the high transmittance and high conductivity of TCFs are mutually restrictive. This creates a primary challenge in developing new flexible TCFs: achieving sufficiently high transmittance while maintaining sheet resistance within an appropriate range. Additionally, a key issue lies in enabling large-area preparation of flexible TCFs at relatively low temperatures. The latter involves properties such as the areal density and mechanical strength of TCFs, which also determine their applicability in future flexible electronics and advanced fields such as aerospace.

There have been several emerging TCF materials primarily include carbon nanofilms, metal nanowires, conductive polymers, etc. Among them, carbon nanofilms have once been considered as the most competitive ideal material to replace ITO TCFs widely used in industry due to their excellent electrical and optical characteristics, flexibility, outstanding stability, and lightweight, radiation-resistant, and ultra-durable properties required for future military applications and aerospace fields. However, the prerequisite for the widespread application of TCFs is not only to possess excellent transparent conductivity but also to be capable of large-scale or even mass production. To date, most research on carbon nanofilms remains in the small-area experimental stage. While only a few studies have proposed several large-area preparation methods, these methods still face technical challenges. Therefore, the preparation method of TCF proposed in this invention aims to achieve large-area preparation of TCFs.

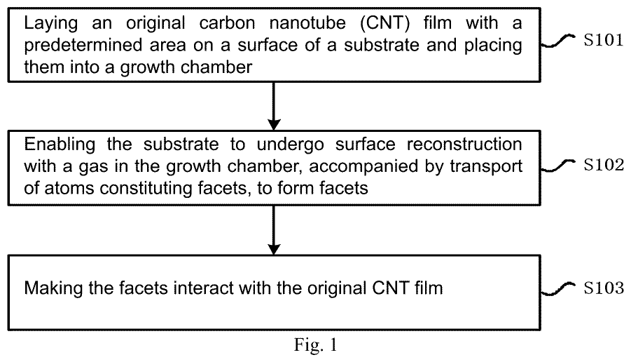

FIG. 1 shows a flowchart of the preparation method of TCF according to one embodiment of the present invention. In this embodiment, the process generally includes:

Step S101: Laying an original CNT film with a predetermined area on a surface of a substrate and placing them into a growth chamber. Here, the original CNT film is a novel material composed of single or multiple layers of CNTs. Microscopically, it forms a two-dimensional continuous network porous structure of CNTs obtained through physical or chemical methods, but its area is limited. This film exhibits excellent properties including being lightweight, possessing high strength, high corrosion resistance, high electromagnetic interference resistance, and good thermal conductivity.

Optionally, the CNTs in the original CNT film may include any one or any combination of the following: single-walled CNTs, double-walled CNTs, few-walled CNTs, and multi-walled CNTs. The thickness of the original CNT film must be greater than 0.1 nm. Preferably, the visible transmittance of the original CNT film is ≥20%. It should be noted that this method does not restrict the preparation method of the original CNT film. Field technicians can determine the preparation method of the original CNT film based on actual conditions. One optional original CNT film could be a directly grown CNT film, and one optional growth method could be the Chemical Vapor Deposition (CVD) method. During the laying process, there are no restrictions on the characteristic dimensions (e.g., length, width, diameter) of the original CNT film. Field technicians can choose according to actual production requirements, such as dividing the characteristic dimensions of the original CNT film into three intervals: ≤10 cm, 10 cm⁻¹ m, ≥1 m, and selecting a corresponding characteristic dimension of the original CNT film based on actual needs.

Optionally, the material of the substrate generally includes, but is not limited to metals, semiconductors, and other compounds. Metals typically include copper, platinum, gold, nickel, titanium, iron, lead, palladium, silver, tungsten, aluminum, zinc, chromium gold, and alloys of several metals. Semiconductors typically include silicon, germanium, gallium arsenide, gallium nitride, indium phosphide, titanium oxide, aluminum oxide, iron sulfide, nickel sulfide, cadmium selenide, etc. Other compounds typically include vanadium oxide, manganese oxide, silicon oxide, etc. Preferably, the material of the substrate can be any one metal or alloy of multiple metals from copper, platinum, gold, nickel, titanium, iron, lead, palladium, silver, tungsten, aluminum, zinc, and chromium gold. Field technicians can select an appropriate substrate material based on actual production requirements.

In some optional embodiments, the substrate needs to be pre-treated to make its surface flat before laying the original CNT film. It should be noted that this method does not specify the pre-treatment method. Some preferred pre-treatment methods may include: mechanical polishing, electrochemical polishing, high-temperature annealing, and combinations of these methods. Field technicians can determine the pre-treatment method of the substrate based on actual conditions. Furthermore, this method does not restrict the area of the substrate. Field technicians can determine the area of the substrate for each preparation (for convenience of explanation, the area of the substrate is denoted as M, the area of the original CNT film as Mᵢ, and the planned growth area of TCF as Mₕ). The area M of the pre-treated substrate needs to be slightly larger than or equal to the planned growth area Mₕ of TCF, i.e., M≥Mₕ. Optionally, the substrate can extend more than 1 mm beyond the edges of the planned TCF growth area. Preferably, the substrate can extend more than 10 mm beyond the edges of the planned TCF growth area.

Optionally, this method does not restrict the area and shape of the original CNT film. Therefore, during the laying process, there may be cases where a single original CNT film cannot reach the set area. Thus, the step of laying the original CNT film of a set area on the surface of the substrate generally includes: laying multiple original CNT films on the surface of the substrate to get complete coverage, ensuring that at least one layer of the original CNT film is on the surface of the substrate. Specifically, take N (N≥1, N is a positive integer) original CNT films and lay them on the surface of the substrate. For any one CNT film Ni (i≤ N), its area Mᵢ≤Mₙ. Subsequently, lay N original CNT films on the surface of the substrate, fully covering the surface of the substrate, while reserving appropriate dimensions on all sides of the substrate. It should be noted that this method does not restrict the spreading method of the original CNT film on the surface of the substrate. Optionally, the spreading method can be: flat laying, interwoven laying, etc. Preferably, the final spreading effect is: when viewed from above, there are no gaps between the CNT films to expose the substrate, and the upper and lower layers can overlap. Ultimately, after laying N original CNT films on the surface of the substrate, the formed multi-layer CNT film should have uniform thickness, and the overall surface should be complete and flat. Field technicians can choose the spreading method based on the actual conditions of the original CNT film and the substrate.

Optionally, after laying the original CNT film of a set area on the surface of the substrate, the method generally further includes: dripping a volatile organic solvent onto the original CNT film to infiltrate it to increase the contact between the original CNT film and the surface of the substrate, after the organic solvent is completely evaporated, the original CNT film on the substrate is placed into the growth chamber. This method does not restrict the type of organic solvent. One preferred example includes ethanol, propanol, butanol, ethylene glycol, isopropanol, acetone, n-hexane, cyclohexane, benzyl ether, chlorobenzene, or any mixture of these organic solvents. Field technicians can choose the corresponding organic solvent based on actual conditions.

Optionally, the growth chamber refers to a region that can assist the original CNT film in completing the growth process on the surface of the substrate, also called the “growth zone.” The growth zone usually refers to a specific region or device whose internal conditions are optimized to support the growth or synthesis of CNT films. Parameters such as temperature (Tₓ), pressure, gas composition, and flow rate inside the growth zone are precisely controlled to provide the best environment for CNT growth. Field technicians can choose the appropriate growth zone to execute this method based on actual conditions.

Step S102: Enabling the substrate to undergo surface reconstruction with a gas in the growth chamber, accompanied by transport of atoms constituting facets, to form the facets. The facets manifest as a regular stepped or zigzag pattern at a mesoscopic scale on the surface of the substrate.

It should be noted that the method of the present invention does not restrict the material of the substrate. Depending on the different materials of the substrate, corresponding reaction gases can be selected to enable surface reconstruction of the substrate, thereby forming facets.

Optionally, the gas used in the growth chamber is capable of interacting with the substrate to cause surface reconstruction and includes either oxidizing or reducing gases, or a mixture of one or more gases of the same category; where “same-category gases” refer to chemically similar gases. For example, multiple same-category gases from oxidizing gases can be selected, such as oxygen, chlorine, bromine, etc. Those skilled in the art can choose the specific type and quantity of reaction gases based on actual conditions. The source of the gas generally includes gases, liquids, solids, or any combination thereof. Those skilled in the art can select the appropriate gas that can interact with the substrate for surface reconstruction based on the actual material and structure of the substrate.

Optionally, steps of the substrate undergoing surface reconstruction with the gas in the growth chamber to form facets include: purging the growth chamber to control the partial pressure of the gas in the growth chamber that interacts with the substrate within a set range; heating the growth chamber to control the interaction between the gas and the surface of the substrate to form facets. Purging refers to the process of removing impurity gases from the mixed gases while controlling the partial pressure of the gas in the growth chamber that interacts with the substrate within a set range. Gases used during purging typically include nitrogen, argon, hydrogen, or a mixture of these gases. Those skilled in the art can determine the specific type of gas used for purging based on actual conditions.

In some optional embodiments of the present invention, when the substrate material is chosen as metal or alloy (e.g., copper), oxidizing gases are generally selected to cause surface reconstruction of the substrate, such as oxygen. Oxygen partial pressure refers to the partial pressure value of oxygen in the gas mixture and is an indicator of oxygen concentration. It reflects the pressure of oxygen in the gas mixture and is usually expressed in units of Torr or Pascal (Pa). The required oxygen partial pressure for different substrate materials to react with oxygen and form facets varies. Optionally, the set range of oxygen partial pressure for different substrates can generally be ≤1 Torr, 1-10 Torr, >10 Torr. Those skilled in the art can select the substrate suitable for forming facets under certain conditions for interacting with the reactants, and determine the set range of oxygen partial pressure corresponding to this substrate based on the specific target product. At the same time, the thickness, rigidity, and flexibility of the substrate are not restricted in principle.

After determining the substrate and controlling the partial pressure of the gas in the growth chamber within a set range, the growth chamber needs to be heated to initiate the interaction between the gas and the surface of the substrate to form facets. The corresponding temperature at this point is denoted as T₁ (the temperature at which the selected substrate begins to show facets). The specific value of temperature T₁ will vary depending on the material of the substrate. When Tₓ=T₁, a transport of atoms or molecules constituting facets occurs on the surface of the substrate, and facets begin to appear on the substrate. At this stage, there has not yet been the formation of new covalent bonds or Y-type network structures between CNTs in the original CNT film, and the interaction between the just-formed facets and the original CNT film (including impurities) is limited, so the reorganization process is not obvious. Optionally, the temperature range for most substrates to form facets can be configured as Tₓ>T₁. In some optional embodiments, preferably, for copper substrates, T₁=700° C.; for nickel substrates, T₁=800° C.

FIG. 4 shows a schematic diagram of the substrate facets according to one embodiment of the present invention. As shown in FIG. 4, the substrate 40 gradually forms stepped or zigzag facets in the growth chamber as the temperature rises. These facets exhibit a stepped morphology, consequently causing the CNTs within these regions to migrate along the undulations and integrate with the CNTs on adjacent surfaces.

Step S103: Making the facets interact with the original CNT film. Through this interaction, impurities in the original CNT film can be removed, and at least part of the CNTs in the original CNT film undergo positional shifts under driving of the facets. Adjacent CNTs or bundles tend to adhere closely together, thus reorganizing the CNT network in the original CNT film to obtain RCNT-TCF.

In some optional embodiments, the original CNT film is generally composed of a CNT network. The step of causing facets to interact with the original CNT film generally includes: continuing heating to allow the facets on the substrate to grow up gradually, thereby controlling the CNT network to gradually adhere to the facets, and the impurities in the original CNT film to gradually dissolve. CNTs in the CNT network move and approach each other as the facets grow up, reorganizing into a new Y-type interconnected network with a long common segment, resulting in RCNT-TCF. These interactions between facets and the original CNT film, under certain conditions (temperature, atmosphere), may occur separately within a certain temperature range in some optional embodiments, or simultaneously occur, or in an intertwine manner. The temperature range for controlling the CNT network to continuously adhere to the facets is generally configured as Tₓ>T₂ (a temperature at which the facets on the selected substrate start to grow up conspicuously and form regularly arranged stepped or zigzag facets). Generally, T₂>T₁; preferably, for copper substrates, T₂=900° C. As the temperature Tₓ increases from T₁ to T₂, the facets grow up gradually and then rapidly. The edges of the facets expand and come into contact with each other, with the contact area continuously expanding. Grooves and depressions form between the facets, eventually forming a regular, neatly arranged stepped or zigzag morphology. During this process, the interaction between the facets and the CNT film (containing impurities) becomes conspicuous. Therefore, at Tₓ=T₂, the facets are provided with sufficient time for their growth process, allowing these conspicuous interactions to persist over an extended period. The reorganization process becomes evident, characterized by: under driving of the facets, more CNTs in the original CNT film tightly adhere to the facets, then move conspicuously, with most CNTs being moved to the grooves between the facets and the depressions formed at the edges of the facets. Neighboring CNTs in the original network approach each other and recombine into new Y-type networks constrained by van der Waals forces with a long common segment. During the process where CNTs in the CNT network move and approach each other as the facets grow up, defects and weak CNTs/bundles, as well as amorphous carbon in the original network are removed. This causes changes in the pore diameter (also called pore size) of the reorganized network. Except for a few pores whose diameters do not change conspicuously, most pore diameters slightly increase or decrease. However, the reorganized network is also constrained by the original network, and the pore diameter of the reorganized network generally does not exceed the larger pores in the original network. Hence, under the dual effects of reorganization caused by driving of the facets and constraint imposed by the original network, the network structure of the RCNT-TCF is optimized, with more uniform pore diameters and reduced film areal density. Due to the difference in types of impurities, the temperature range for gradual dissolution of impurities is generally configured as Tₓ≥T_{L} (the lowest temperature at which the facets start to dissolve any impurity). Generally, when Tₓ≥T_{L}, because of the interactions between the facets and the original CNT film, some conditions are the same while others differ, and the duration of the processes varies. Different interactions may intertwine. In some optional embodiments, for copper substrates, when Tₓ=T₂=900° C.≥T_{L}, the facets continuously dissolve impurities (such as catalyst particles, amorphous carbon, defects, and fine CNTs) that tightly adhere to the facets through processes like alloying, diffusion, and solid solution formation, removing the majority, if not all of these impurities. Subsequently, a larger continuous Y-type interconnected network with a long common segment is freshly formed, further reducing areal density. Conspicuous reorganization occurs during the constant temperature process at Tₓ=T₂, where the entire original CNT network film is basically reorganized through interactions between the facets, CNTs, and impurities, forming a new large-area Y-type interconnected network with a long common segment, completing the reorganization of the original CNT film. Thus, under the dual effects of reorganization caused by driving of the facets and constraint imposed by the original network, the network structure of the RCNT-TCF is optimized. Compared to the original CNT film, the roughness decreases, the pore diameters become more uniform, and the film's areal density decreases.

FIG. 5A shows a schematic diagram before the reorganization of the CNT network under driving of the facets according to one embodiment of the present invention, and FIG. 5B shows a schematic diagram during the reorganization process under driving of the facets. As shown in FIG. 5A, the CNT network is laid on the surface of the substrate. As the facets gradually form and grow up, the CNT network moves under driving of the facets, causing the CNTs in the network to gradually reorganize as shown in FIG. 5B.

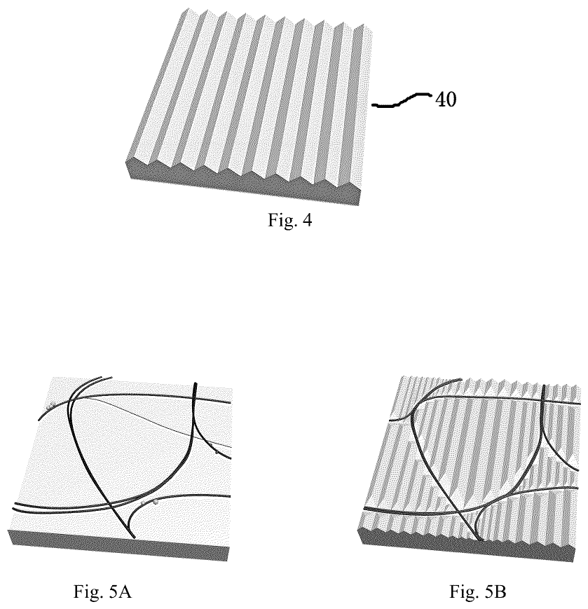

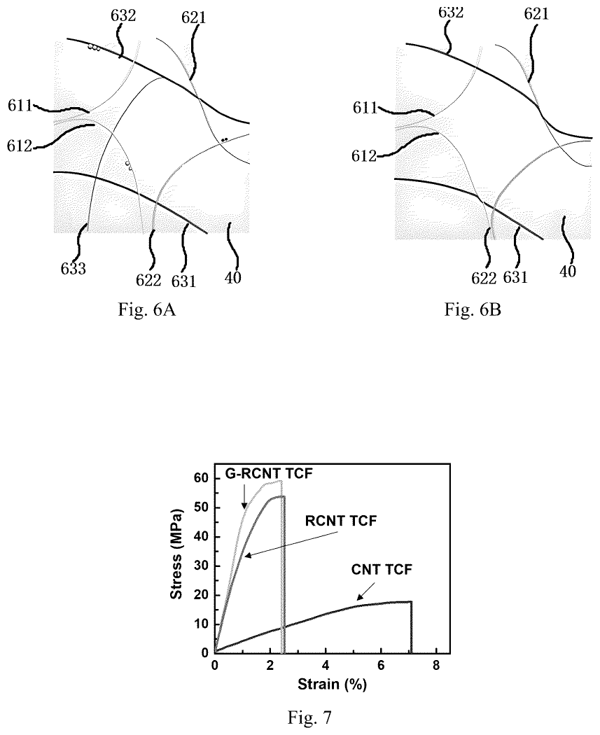

In some optional embodiments, in Step S101, there are multiple layers of spliced original CNT films on the surface of the substrate. Under driving of the facets, CNTs from different layers approach and connect together at the splicing areas, leading to the reorganization of the CNT network. The pore sizes in the reorganized network change compared to those in the original CNT film. Generally, an increase in pore size is accompanied by a corresponding increase in the inter-nodal bundle length while a decrease in pore size results in a reduction of the inter-nodal bundle length. The result of the reorganization under driving of the facets is that CNTs from different layers merge into a single large-area Y-type interconnected network with a long common segment. Ultimately, the network structure of the spliced CNT film is reorganized and optimized, forming a new continuous large-area network, thus obtaining the RCNT-TCF. FIG. 6A shows a schematic diagram before the reorganization of the spliced multi-layer CNT network under driving of the facets according to one embodiment of the present invention, and FIG. 6B shows a schematic diagram during the reorganization process. As shown in FIG. 6A, there are three layers of original CNT films on the facets 40. The first layer contains CNTs 611 and 612, the second layer contains CNTs 621 and 622, and the third layer contains CNTs 631, 632, and 633. After reorganization caused by driving of the facets, CNTs from different layers form new connections, creating a single large-area, clean, flat, and a continuous Y-type interconnected network with a long common segment, as shown in FIG. 6B.

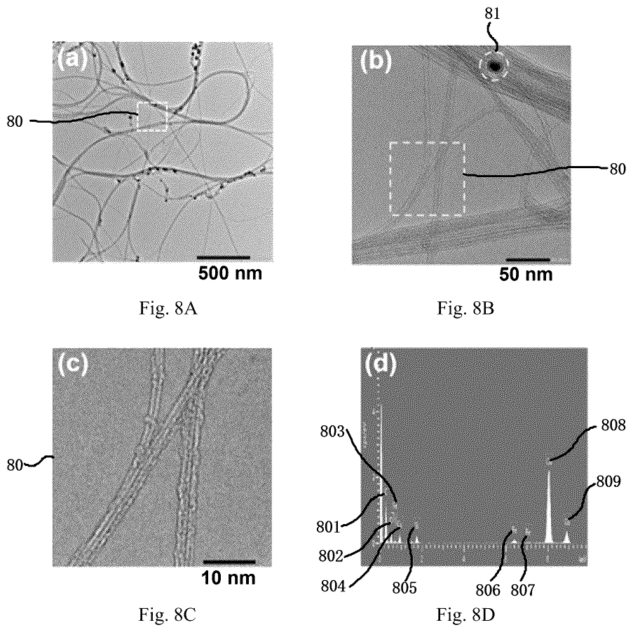

FIG. 8A-8C show typical HRTEM images of the original CNT with a scale bar of 500 nm, 50 nm and 10 nm, respectively, according to an embodiment of the present invention; and FIG. 8D shows the EDS results of the present invention. As shown in FIG. 8A, there are multiple CNTs in the dashed box 80. The image of the CNTs under a scale bar of 50 nm is shown in FIG. 8B, and the image under a scale bar of 10 nm is shown in FIG. 8C, revealing a Y-junction structure feature. Additionally, as shown in FIG. 8B, there are catalyst particle impurities 81, and their EDS results are shown in FIG. 8D, where 801 is C, 802 is O, 803, 806, and 807 are Fe, 804, 808, and 809 are Cu, and 805 is Si, indicating the presence of impurities Fe in the spectrum.

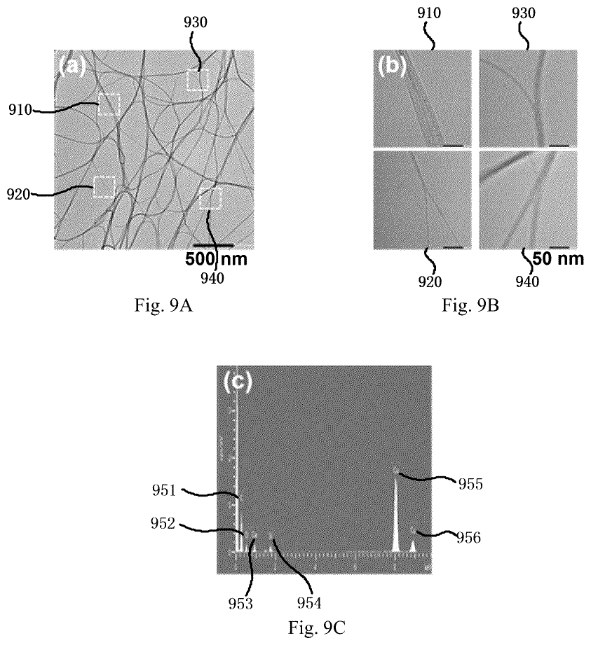

FIGS. 9A and 9B show typical HRTEM images of the RCNT with a scale bar of 500 nm and 50 nm, respectively, according to one embodiment of the present invention; and FIG. 9C shows an EDS result of the RCNT according to one embodiment of the present invention. As shown in FIG. 9A, the network film composed of RCNTs contains many Y-junctions, including dashed boxes 910, 920, 930, and 940. Their enlarged images are shown in FIG. 9B, showing that after reorganization, Y-junction structures exist in each dashed box. Furthermore, as shown in FIG. 9C, 951 is C, 952 is O, 953, 955, and 956 are Cu, and 954 is Si. Impurities Fe originating from catalyst particles 81 have completely disappeared. Therefore, compared to the original CNT film, the RCNT-TCF exhibits more Y-junction structures, optimizing the CNT network structure.

FIG. 12A shows an SEM image of the initial morphology of two pieces of CNT films overlapping on a surface of copper foil according to an embodiment of the TCF preparation method in this invention. FIG. 12B shows an SEM image of the RCNT-TCF with the copper foil after reorganization, as per the same embodiment of the same method. In FIG. 12A, there are two outlined areas, Frame 1 and Frame 2. Frame 1 represents the first layer of the original CNT film on the surface of the substrate, while Frame 2 represents the second layer of the original CNT film. After the reorganization process described in this method, the result is shown in FIG. 12B. In FIG. 12B, the dashed lines represent CNTs. In the loop shown, it can be observed that the dashed lines 1 and 2 from FIG. 12A have been reorganized into a Y-type structure. The unconnected or X-type junctions between CNTs from different layers undergo position migration due to reorganization by driving of the facets, causing adjacent bundles to align closely and form new Y-type connections. Some X-type junctions also transform into robust Y-type connections.

In other optional embodiments, the step of facilitating interaction between facets and the original CNT film may further include continuing heating until the temperature Tₓ increases from T₂ to T₃ (the temperature at which the surface of the substrate begins to melt), at which point the morphological features of the facets start to disappear. The temperature range for the gradual disappearance of morphology of the facet is configured as Tₓ≥T₃. In some embodiments, preferably for a copper substrate, T₃=1030° C. When the heating temperature reaches the range where the facets' morphological features gradually vanish (i.e., Tₓ≥T₃), the CNT network reorganization process is completed. Since T₃ approaches or equals the melting point of the substrate, pre-melting of the surface of the substrate becomes more evident, the morphological features of the facets significantly disappear, and the reorganization process is complete, meanwhile the large-area Y-type interconnected network structure is preserved. Additionally, as the facets diminish, nearly all impurities are removed, resulting in a clean, intact RCNT network film on the surface of the substrate. Therefore, under the dual effects of reorganization under driving of the facets and the constraint of the original network, the network structure of the RCNT-TCF is further optimized. Compared with the original CNT film, the roughness of the reorganized network film decreases, the porosity becomes uniform, and the areal density of the RCNT-TCF reduces. In an embodiment of the method for preparing TCFs of the present invention, an areal density of the G-RCNT TCF is measured to be 1.5 μg/cm², which is less than that of the original CNT film (˜2.0 μg/cm²).

It should be noted that the specific numerical values of the various temperature ranges mentioned above are examples for certain substrate materials under general conditions. Field technicians can determine the specific temperature range corresponding to different operations based on the actual substrate material.

The RCNT-TCF obtained through this method, when used as a TCF, forms a more efficient conductive network internally compared to the original CNT film, improving the performance of the TCF. Furthermore, it can achieve free-standing properties and enable large-area preparation.

In some embodiments, nano carbon material TCFs primarily include CNT films (CNT-TCF), graphene films (G-TCF), and hybrid films of CNT and graphene (G-CNT TCF). These films are mainly grown via chemical vapor deposition (CVD). A single-layer graphene film exhibits a transmittance as high as 97.7%, a room-temperature carrier mobility of 2.5×10⁵ cm²/(V·s), and theoretically a Young's modulus of 1050 GPa. However, intrinsic defects exist in CVD-grown graphene films, and the single-atom layer is difficult to maintain structural integrity independently without the support of a solid-phase substrate during the subsequent transfer process, i.e., free-standing or self-supporting. Although large-area preparation is possible, polymer-assisted transfer methods such as heat-peeling tape, silicone rubber, or EVA must be used. This not only significantly increases the complexity of the process but also inevitably introduces contamination and damage to the G-TCF, severely affecting its quality and physical/chemical properties. Especially after transfer, the sheet resistance of G-TCF often reaches hundreds of ohms or even exceeds 1000 Ω/sq. Another typical representative of nano carbon material TCFs is CNT-TCF. Theoretically, a single-wall CNT has a room-temperature carrier mobility of up to 10⁵ cm²/(V·s) and a Young's modulus of approximately 1 TPa. However, due to inter-tube tunneling barriers and scattering caused by catalyst particles and other impurities, the sheet resistance of CNT-TCF at 90% transmittance is often in the hundreds of ohms. For larger-area CNT-TCFs (with side lengths or diameters ≥10 cm) with low junction resistances and other excellent structures, the sheet resistance can be below 200 Ω/sq but still higher than 100 Ω/sq. During the batch preparation of transparent conductive single-wall CNT films (SWCNT-TCF), even using blow-up aerosol CVD (BACVD), SWCNT-TCF can be free-standing and continuously prepared. However, during continuous preparation, although the length of SWCNT-TCF can be unrestricted, its width is difficult to expand due to a limitation of growth principle. On the other hand, free-standing multi-wall CNT TCFs (MWCNT-TCF) prepared by super-aligned array spinning dry methods can expand in area, but their transmittance and conductivity are far inferior to those of BACVD-prepared single-wall CNT films.

In other embodiments, to mitigate the adverse effects on graphene quality (such as contamination and cracking) caused by polymer-assisted transfer, a G-CNT TCF (G-CNT TCF) is prepared wherein graphene fills the pores in the CNT network. This structure combines the advantages of both graphene and CNTs. The mechanical strength of CNTs not only facilitates the transfer of graphene to the target substrate without polymer assistance but also provides graphene with a one-dimensional conductive pathway. High-quality graphene acts as a conductive plane filling the pores of the CNT network, connecting non-contacting CNTs and reducing tunneling barriers, thus enhancing the carrier transport efficiency of the CNT network. In some photovoltaic heterojunctions, the filling of graphene can greatly increase the contact area between CNTs and other semiconductors, significantly enhancing the carrier collection efficiency of the hybrid film. Therefore, devices based on G-CNT TCF often exhibit better performance than those based on single component (G-TCF, CNT-TCF), and are expected to play a crucial role in some high-end or specialized applications (such as high-stability solar cells). However, G-CNT TCF remains in small-scale laboratory preparation stages (2 cm×2 cm on PET, with free-standing areas on water even smaller at 1 cm×1 cm). Although multiple preparation methods have been developed, the sheet resistance of small-area G-CNT TCF with transmittance above 85% is still over 100 Ω/sq. Due to the insufficient transmittance and conductivity of directly grown G-CNT TCF that do not meet industrial application standards, post-processing methods such as chemical doping (HNO₃, AuCl₃, TFSA, etc.) or substrate deposition (nickel, gold, etc.) are often employed to enhance conductivity. However, these methods introduce other elements into the G-CNT TCF, facing issues of poor stability, high cost, and complex processes, and most dopants and metals reduce the transmittance of the film and increase its areal density. Moreover, since the transmittance and conductivity of G-CNT TCF are mutually constrained, these methods can only improve the conductivity of the film singly, potentially decreasing its transmittance, failing to simultaneously enhance both transmittance and conductivity.

In some preferred embodiments of this invention, to further enhance the performance of TCFs, the step of initiating interaction between facets and the original CNT film may further include introducing a carbon source and an auxiliary gas into the growth chamber to grow graphene within the reorganized uniform CNT network, thereby forming G-RCNT TCF. Technicians in this field can choose the carbon source and corresponding auxiliary gases based on actual conditions. FIG. 19-21 show optical images of the free-standing large-area G-RCNT TCFs prepared according to several embodiments of the present invention.

Through the method for preparing TCFs presented in this invention, the network structure of the hybrid film can be reorganized microscopically, resulting in synergistically enhancing the transmittance, conductivity, mechanical strength, cleanliness, flatness, and other properties of G-RCNT TCF. Moreover, this method is scalable and capable of large-area preparation, enabling the fabrication of G-RCNT TCF with unrestricted length and width. Simultaneously, this method can be scaled for batch and continuous production of large-area G-CNT TCF. The flexible transparent conductive G-CNT TCF prepared by this method can be used at any temperature. FIG. 7 shows the mechanical strength test results of the original CNT film and G-RCNT TCF in one embodiment of the TCF preparation method of this invention. As shown in FIG. 7, the mechanical strength of G-RCNT TCF is significantly improved compared to the original CNT film.

In some preferred embodiments, during heating in the aforementioned embodiments, the heating rate can be selected within the range of 0-20° C./min. An appropriate temperature Tₓ can be maintained for a certain duration to ensure sufficient time for growth of the facets, CNT reorganization, and graphene growth. One optional example of temperature Tₓ can be ≥T₁, and one optional example of time t can be ≥0 min, 0-10 min, 10-60 min, or >60 min. Field technicians can determine the required holding time at different temperatures and the specific heating rate based on actual conditions.

Optionally, after the step of initiating interaction between facets and the original CNT film, it may further include cooling the RCNT-TCF or G-RCNT TCF at a preset cooling rate. Subsequently, make the cooled RCNT-TCF or G-RCNT TCF with substrate float on an etchant to etch off the substrate, leaving the cooled RCNT-TCF or G-RCNT TCF floating on the surface of the etchant, followed by rinsing. The substrate etchant can vary depending on the substrate material and structure. In some embodiments of this invention, the substrate etchant generally includes ammonium persulfate solution, ferric chloride solution, hydrochloric acid solution, or a mixture of hydrochloric acid and hydrogen peroxide solution. Field technicians can choose the substrate etchant based on actual conditions. Some optional examples of the preset cooling rate include <10° C./min, 10-100° C./min, >100° C./min, with a preferred embodiment being 100° C./min.

The rinsing process employs a rinse liquid to remove the substrate etchant. The selection of the rinse liquid depends on the substrate etchant. Preferably, deionized water is used as the rinse liquid. Field technicians can choose the rinse liquid based on actual conditions. Optionally, the rinse step generally includes using preferred deionized water for rinsing. After rinsing with deionized water, a polymer-free transfer can yield a large-area RCNT-TCF or G-RCNT TCF free-standing on water or even in air. The free-standing RCNT-TCF or G-RCNT TCF can then be transferred to any substrate without damage.

Optionally, the performance characterization of the RCNT-TCF or G-RCNT TCF obtained by this method can be characterized by the formula shown in equation (1):

$$FOM = \frac{188.5}{{R}_{s q} ( {T}^{- \frac{1}{2}} - 1 )} \qquad Equation ( l )$$

where FOM represents the figure of merit, R_{sq} represents the sheet resistance, and T represents the transmittance. In addition, various properties of the large-area G-RCNT TCF obtained, such as morphology, microstructure, and mechanical properties, can also be characterized.

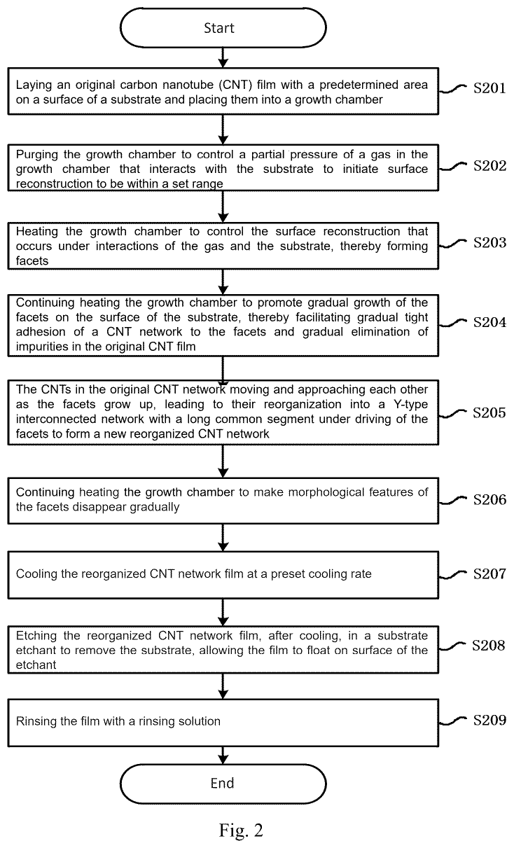

FIG. 2 is a flowchart of the preparation method of TCF according to another embodiment of the present invention. In some optional embodiments, this process generally includes:

Step S201: Laying an original CNT film with a predetermined area on a surface of a substrate and placing them in a growth chamber.

Step S202: Purging the growth chamber to control a partial pressure of a gas in the growth chamber that interacts with the substrate to initiate surface reconstruction to be within a set range.

Step S203: Heating the growth chamber to control the surface reconstruction that occurs under interactions of the gas and the substrate, thereby forming facets.

Step S204: Continuing heating the growth chamber to promote gradual growth of the facets on the surface of the substrate, thereby facilitating gradual tight adhesion of a CNT network to the facets and gradual elimination of impurities in the original CNT film. Skilled artisans can determine the temperature range for heating based on an actual material of the facets.

Step S205: The CNTs in the original CNT network moving and approaching each other as facets grow up, leading to their reorganizing into a Y-type interconnected network with a long common segment under driving of the facets to form a new reorganized CNT network.

Step S206: Continuing heating the growth chamber to make morphological features of the facets disappear gradually.

Step S207: Cooling the reorganized CNT network film at a preset cooling rate.

In some optional embodiments, an oxidative gas (such as oxygen) interacts with the substrate. For example, the original CNT film and copper foil can be heated to 900° C. under an oxygen partial pressure of 10⁻¹ Torr and maintained for 30 minutes before rapid cooling. The SEM image of the resulting RCNT-TCF/copper foil is shown in FIG. 11. FIG. 11A shows the SEM image of the original CNT film and copper foil according to one embodiment of the preparation method of TCF of the present invention; FIG. 11B shows the SEM image of the RCNT-TCF and copper foil according to one embodiment of the preparation method of TCF of the present invention. In FIG. 11A, the SEM image of the original CNT film/copper foil is displayed at a scale bar of 500 nm. In FIG. 11B, the SEM image of the RCNT-TCF/copper foil obtained by heating to 900° C. under an oxygen partial pressure of 10⁻¹ Torr and maintaining for 30 minutes followed by rapid cooling is displayed at a scale bar of 500 nm. The dashed line 1 in FIGS. 11A and 11B highlights a CNT whose position has moved after the high-temperature process. Dashed line 2 highlights two originally parallel CNTs that are now closely adjacent after the high-temperature process. The arrows indicate the tendency of multiple CNTs to aggregate after the high-temperature process. The dashed circle highlights the process where a string of impurities tightly adhered to the surface of copper dissolves and disappears after the high-temperature process.

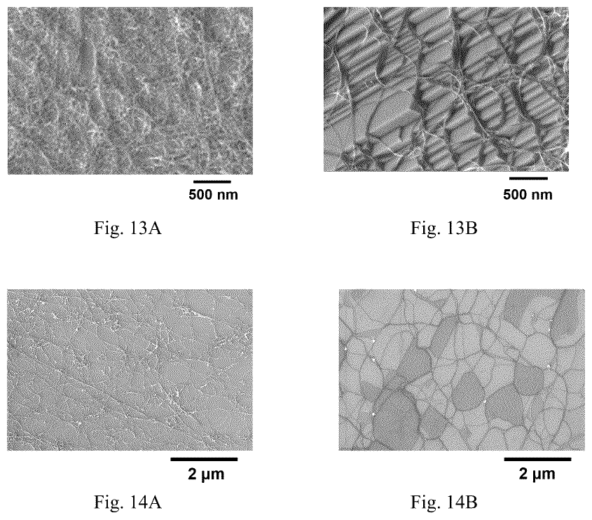

In some other optional embodiments, when the original CNT film on the surface of the substrate is two layers, FIG. 13A shows the SEM image of the original two-layer CNT film on copper foil, and FIG. 13B shows the SEM image of the RCNT-TCF on copper foil, according to one embodiment of the preparation method of TCF of the present invention. FIG. 13B displays the SEM image of the RCNT-TCF/copper foil obtained by heating the original two-layer CNT film on copper foil in FIG. 13A to 900° C. under an oxygen partial pressure of 10⁻¹ Torr and maintaining for 60 minutes followed by rapid cooling. It is clearly visible that the two layers of multiple CNTs reorganize together under the action of the facets, forming a Y-type interconnected network with a long common segment.

Step S208: Etching the reorganized CNT network film, after cooling, in a substrate etchant to remove the substrate, allowing the film to float on surface of the etchant.

Step S209: Rinsing the film with a rinsing solution.

Through this method, the CNTs inside the original CNT film can be reorganized under driving of the facets to form a Y-type interconnected network with a long common segment, obtaining the RCNT-TCF, which reduces the film's areal density. Compared to the original CNT film, the RCNT-TCF forms a more efficient conductive network internally, improving the performance of the TCF, while also achieving free-standing properties. Moreover, this method enables large-area preparation of TCF.

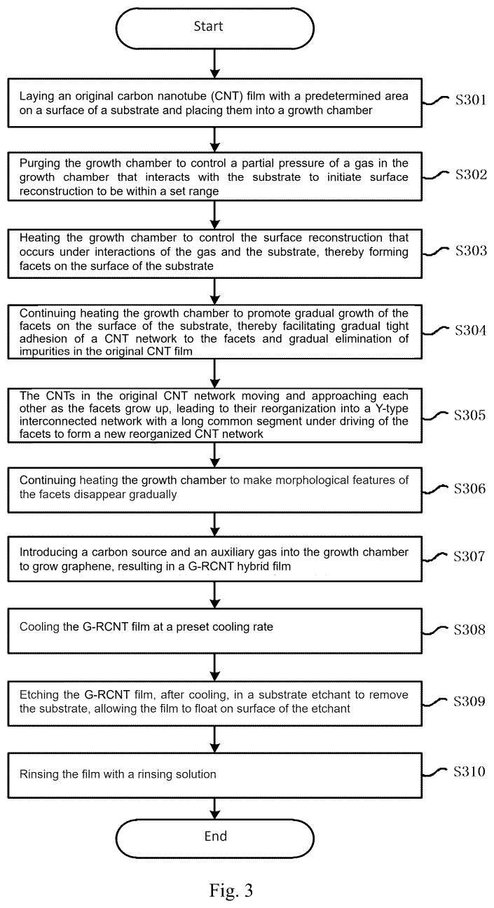

FIG. 3 is a flowchart of the preparation method of TCF according to yet another embodiment of the present invention. In some optional embodiments, this process generally includes:

Step S301: Laying an original carbon nanotube (CNT) film with a predetermined area on a surface of a substrate and placing them into a growth chamber.

Step S302: Purging the growth chamber to control a partial pressure of a gas in the growth chamber that interacts with the substrate to initiate surface reconstruction to be within a set range.

Step S303: Heating the growth chamber to control the surface reconstruction that occurs under interactions of the gas and the substrate, thereby forming facets on the surface of the substrate.

Step S304: Continuing heating the growth chamber to promote gradual growth of the facets on the surface of the substrate, thereby facilitating gradual tight adhesion of a CNT network to the facets and gradual elimination of impurities in the original CNT film.

Step S305: The CNTs in the original CNT network moving and approaching each other as the facets grow up, leading to their reorganization into a Y-type interconnected network with a long common segment under driving of the facets to form a new reorganized CNT network.

Step S306: Continuing heating the growth chamber to make morphological features of the facets disappear gradually. A network pore structure already formed by the CNTs will be preserved.

Step S307: Introducing a carbon source and an auxiliary gas into the growth chamber to grow graphene, resulting in a G-RCNT hybrid film.

Step S308: Cooling the G-RCNT film at a preset cooling rate.

Step S309: Etching the G-RCNT film, after cooling, in a substrate etchant to remove the substrate, allowing the film to float on surface of the etchant.

Step S310: Rinsing the film with a rinsing solution. In some preferred embodiments, deionized water is generally used for rinsing.

This method combines the CNT network reorganization technique with the graphene growth process to prepare large-area G-RCNT TCF. There is no limitation on the size of the hybrid film prepared by this method, which can be set according to requirements, with both length and width being scalable (optional embodiments include: <10 cm, 10 cm-1 m, >1 m, etc.). Since the RCNT network process of driving of the facets enhances the mechanical strength of the reorganized network, thereby getting rid of traditional polymer-assisted transfer methods that usually cause contamination and damage during substrate removal, which simplifies the transfer process, obtaining a clean, free-standing large-area G-RCNT TCF on water as well as a free-standing large-area G-RCNT TCF in air. The free-standing G-RCNT TCF can also stay intact when transferred to any substrate. At the same time, its quality and various performances (transmittance, conductivity, mechanical strength, cleanliness, flatness, etc.) have been improved in synergy. The obtained product provides a material basis for further research and application of G-CNT TCF.

Below is a detailed introduction to the beneficial effects of the RCNT-TCF and G-RCNT TCF prepared by the present invention compared to existing carbon nanofilms.

1. This method can simultaneously enhance the transmittance and conductivity of the original CNT film.

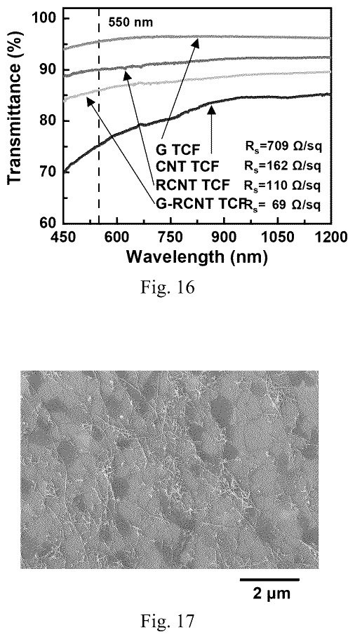

When the original CNT film is laid on a surface of a substrate under conditions where facets can grow up without damaging the CNTs, under driving of the facets, the original CNT film will adhere tightly to the surface of the substrate at the microscopic level. Defective CNTs with fewer defects, catalyst particles, and amorphous carbon impurities in the film dissolve into the substrate (defect sites have higher reactivity). Meanwhile, the CNTs relocate under driving of the facets, leading adjacent bundles to align closely. Consequently, the pore structure of the film changes, and the length between nodes increases, forming a large-area Y-type interconnected network. This significantly reduces the film's areal density. The CNT network reorganization process of driving of the facets forms a more efficient conductive network, resulting in a significant simultaneous improvement in the sheet resistance and transmittance of RCNT-TCF and G-RCNT TCF, breaking the mutual constraint between transmittance and conductivity in TCFs. FIG. 16 shows the transmittance-conductivity test results for various TCFs prepared according to one embodiment of this invention. As shown in FIG. 16, the G-RCNT TCF prepared by this method achieves a sheet resistance of less than 70 Ω/sq at 86% transmittance without doping or post-processing. Compared to the original CNT film, the conductivity of G-RCNT TCF improves by over 2.3 times, transmittance increases by over 11%, and the figure of merit exceeds 35 (increased by over 4 times), meeting industrial requirements for flexible TCFs. Therefore, this G-RCNT TCF exhibits enhanced transmittance and conductivity, which holds important application value in flexible electronics and optoelectronic device manufacturing.

Current post-treatment methods such as doping and metal deposition do not fundamentally alter the CNT network structure but merely add substances beneficial to conductivity, which can only singly enhance the film's conductivity while potentially reducing its transmittance, failing to achieve simultaneous enhancement of both properties. Compared to chemical doping and metal deposition, the CNT network reorganization method has many advantages: (1) No additional elements are introduced, avoiding increased areal density of G-RCNT TCF and limiting its application scenarios. (2) It does not change the conductive type of G-RCNT TCF (semiconducting or metallic), preserving its intrinsic properties. (3) It avoids issues like dopant failure (decomposition, volatilization, hydrolysis) and metal corrosion, ensuring long-term stability of G-RCNT TCF. (4) It avoids problems such as expensive dopants and metals, complex deposition processes, making it a simple and cost-effective method.

### 2. Enhancement of Mechanical Strength.

Currently, the largest area of G-CNT TCF that can be free-standing on water is only 1 cm×1 cm. In the method of CNT network reorganization caused by driving of the facets, proposed in this invention, the CNTs relocate under driving of the facets, adjacent bundles tend to align closely, forming more robust Y-type connections. The CNT reorganization process optimizes the network structure of G-RCNT TCF. RCNT-TCF has a Young's modulus exceeding 40 MPa, surpassing traditional CNT films by more than 8 times. Thus, G-RCNT TCF based on RCNT-TCF can be free-standing on water, even in air. The free-standing area of RCNT-TCF and G-RCNT TCF in air is at least 1 cm², and even >2 cm×2 cm (>4 cm²). Even when expanded to meter-scale sizes (<10 cm², 10 cm²-1 m², >1 m²), RCNT-TCF and G-RCNT TCF can still be free-standing on water. Free-standing RCNT-TCF or G-RCNT TCF can also be transferred to any substrate without damage.

Most existing TCFs are fabricated directly on a substrate and cannot be free-standing without a solid phase substrate. Consequently, the optical, mechanical, and even electrical properties of TCFs are limited by the substrate. This makes it difficult for advanced flexible and ultra-thin devices based on these TCFs to achieve qualitative improvements in performance. Moreover, non-free-standing TCFs cannot be applied in some devices based on special principles (e.g., radiative thermal photodetectors, thermoacoustic speakers). The free-standing, flexible, and large-area RCNT-TCF and G-RCNT TCF prepared using the method proposed in the present invention are expected to solve these problems.

### 3. Significant Improvement in Cleanliness and Application Scenarios.

Under conditions where facets can grow up without damaging the CNTs, under driving of the facets, the CNT film adheres tightly to the surface of the substrate at the microscopic level. Defective CNTs with fewer defects, catalyst particles, and amorphous carbon impurities in the film dissolve into the substrate (defect sites have higher reactivity). Thus, this method not only enhances the transmittance-conductivity and mechanical strength of RCNT-TCF and G-RCNT TCF but also removes catalyst particles and other impurities from the reorganized film, significantly improving the cleanliness of the reorganized film and broadening the application scenarios of RCNT-TCF and G-RCNT TCF.

CNTs prepared by chemical vapor deposition inevitably contain many catalyst particles (mostly transition metals), which not only increase light absorption but also affect the film's conductivity due to scattering centers caused by catalyst particles. Additionally, extra metal elements limit the film's applicability in special environments (e.g., non-magnetic environments). In this invention, as the facets grow up, the CNT network adheres tightly to the metal surface, facilitating catalyst particles and amorphous carbon contaminants to dissolve directly upon contact with the metal surface. Removing these impurities reduces carrier scattering and avoids light absorption caused by impurities, resulting in G-RCNT network films with higher conductivity and transmittance.

Moreover, since catalyst particles are often transition metals, especially magnetic iron particles, traditional RCNT-TCF and G-RCNT TCF may not be suitable for certain special scenarios, such as precision electron microscope chambers where magnetic iron particles could damage equipment. RCNT-TCF and G-RCNT TCF purified by removing catalyst particles and other impurities have broader application scenarios.

### 4. Significant Improvement in Flatness.

The CNT reorganization process optimizes the network structure of the CNT film, forming tighter connections between adjacent bundles while removing catalyst particles and other impurities from the network. This greatly reduces the surface roughness of RCNT-TCF and G-RCNT TCF, significantly enhancing the micro-level flatness of these reorganized films.

In some devices based on CNT films, especially for ultra-thin devices such as flexible organic solar cells and liquid crystal switchable windows, the rough microscopic surface of CNT films is highly prone to short circuits, drastically reducing device yield.

The RCNT-TCF and G-RCNT hybrid network in this invention has extremely low surface roughness (Rq as low as ˜2 nm, reduced by about 10 times compared to the original CNT network). This directly addresses the frequent short circuits and breakdowns caused by excessively high surface roughness in CNT-based electronic and optoelectronic devices, significantly improving device yield and enabling broader applications of RCNT-TCF and G-CNT TCF.

5. Large-Area and Scalable Fabrication of TCFs with Environmental Friendliness.

Any new TCF method must be capable of large-area or scalable fabrication to be meaningful in industrial production. Only large-area TCFs can meet the demands of practical devices and equipment, and scalable production is essential for satisfying market demand, improving product quality, and reducing costs. However, most new TCF methods are still confined to small-area (several centimeters) laboratory research stages, with very few methods currently capable of large-area or scalable (tens of centimeters or even meters) TCF preparation. Furthermore, these methods still have certain issues.

Due to insufficient mechanical properties, graphene films are difficult to be free-standing, especially during large-area fabrication, requiring auxiliary transfer via heat-peelable tape, silicone gel, EVA, or other polymers. This not only significantly increases process complexity but also inevitably introduces contamination and damage to G-TCF, severely affecting its quality and physical/chemical properties. Although the transferred G-TCF can reach meter-scale areas, its sheet resistance is often hundreds of ohms or even exceeds 1000 Ω/sq, greatly limiting its practical application. For CNT films, transparent conductive single-walled CNT films (SWCNT-TCF) have been batch-fabricated in previous work, and SWCNT-TCF can even be continuously fabricated in a free-standing manner through blow-up aerosol CVD (BACVD). However, during continuous fabrication, although the length of SWCNT-TCF can be unrestricted (up to tens of meters), its width is difficult to expand (<10 cm) due to the limitation of the growth principle. For free-standing multi-walled CNT TCF (MWCNT-TCF) prepared by super-aligned array spinning dry method, although the area can be expanded (width up to tens of centimeters, length up to meters), its transmittance-conductivity (transmittance below 85%, sheet resistance in thousands of ohms) is far inferior to SWCNT films prepared by BACVD, limiting the practical application of MWCNT-TCF.

The RCNT-TCF preparation method provided by this invention can achieve large-area and scalable expansion of RCNT-TCF. The original CNT film area is expanded through stitching. At the stitching areas, unconnected or X-type connected CNTs from different layers undergo position migration after reorganization under driving of the facets, adjacent bundles tend to align closely to form new Y-type connections, and some X-type connections can also form robust Y-type connections. For several-layer stitched CNT films, after reorganization under driving of the facets, they connect into a single-layer large-area Y-type interconnected network film. Ultimately, under the dual effects of reorganization under driving of the facets and constraint from the original network, the network structure of the stitched CNT film is optimized, forming a continuous large-area film while reducing its areal density. The prepared CNT film can be free-standing, with a free-standing area of at least 1 cm². In some embodiments, A3-sized or even meter-scale free-standing RCNT-TCF has been prepared, proving that this technology can scale up further. Subsequently, graphene hybrid growth is performed to obtain large-area G-RCNT TCF with excellent network structure. The preparation method of this invention can produce both RCNT-TCF and RCNT-TCF-graphene hybrid films with no size restrictions for either type thereof. Dimensions (length, width, diameter, etc.) can be expanded as needed (<10 cm, 10 cm-1 m, >1 m).

The G-RCNT TCF preparation method provided by this invention can achieve large-area and scalable expansion, producing free-standing G-CNT TCF with an area of at least 1 cm². In some embodiments, A3-sized or even meter-scale free-standing G-RCNT TCF has been manufactured, proving that this technology can scale up further. This invention achieves the first large-area preparation of G-CNT TCF, filling a research gap in this field.

Furthermore, this invention is devoid of any toxic or harmful substances, benefiting environmental protection during mass production. Throughout the preparation process, no toxic or harmful substances are used, making it an environmentally friendly production method, which is crucial for future industrial production.

The lightweight, high-strength, highly transparent and conductive, and large-area producible RCNT-TCF and G-RCNT TCF demonstrate broad application prospects in flexible electronics, optical engineering, artificial intelligence, modern architecture, transportation, and even aerospace.

### 6. Network Structure Optimization and New Design Perspectives.

The mechanism of CNT network reorganization under driving of the facets provided by this invention optimizes the network structure of RCNT-TCF and G-CNT TCF. Due to the formation and growth of facets on the surface of the substrate, the bundles in the original CNT film undergo positional migration, changes in bundle spacing, and variations in node-to-node bundle lengths. A large number of adjacent bundles gather together to form stronger connections. The pore diameter in the network tends to be uniform, generally around 2 μm. Meanwhile, the poorer-quality parts and catalyst particles in the CNT network adhering to the facets dissolve first, following a “survival of the fittest” principle, reducing the areal density of the reorganized network film. Ultimately, under the dual effects of reorganization under driving of the facets and constraint from the original network, the CNT network reorganizes into a large-area Y-type interconnected network, forming a more efficient conductive network and a more robust mechanical structure. The optimized network structure enhances multiple properties of G-CNT TCF (transmittance, conductivity, mechanical strength, cleanliness, flatness, etc.).

Previous studies involving heating CNT films/substrates (e.g., Cu substrates) under a reducing environment excluded the presence of oxidizing gases (such as oxygen), thereby preventing the formation of facets. In optional embodiments of this invention, it was found that under these conditions, the CNT bundles do not undergo conspicuous positional migration, and the film does not exhibit noticeable carbon consumption. Thus, the network structure of the CNT film and G-CNT TCF exhibits minimal alteration before and after treatment, failing to optimize the film's network structure.

This CNT network structure optimization method provided by this invention not only provides new perspectives for TCF structural design and performance optimization but also offers new ideas for research on other types of films (e.g., high-strength films, ultra-flat films) and impurity removal in films.

Below is a detailed description of the method for preparing a large-area free-standing RCNT-TCF and G-RCNT TCF of the present invention.

### Embodiment 1: Preparation Method of Reorganized G-CNT TCF

(1) Growing a CNT film:

Using the CVD method to grow a single-walled CNT film.

In this embodiment, a free-standing continuous network CNT film is used (transmittance 75%, sheet resistance 162 Ω/sq, figure of merit 7.6).

(2) Polishing a copper foil electrochemically to make its surface smooth.

(3) Placing the CNT film flat on a surface of the copper foil (i.e., CNT film/copper foil). Preferably, adding a few drops of ethanol to wet the CNT film/copper foil interface for better contact.

(4) After the organic solvent evaporates, placing the CNT film/copper foil into a growth chamber of a heating furnace. Purging the growth chamber to maintain an oxygen partial pressure in the growth chamber less than 10⁻¹ Torr.

(5) Setting up a heating program to heat the CNT film/copper foil. When the heating temperature exceeds T₁=700° C., obvious facets appear on the copper foil surface. As the temperature continues to rise, the facets gradually grow. When the heating temperature reaches T₂=900° C., the step width of the facets approaches 100 nm, and the interaction between the original CNT film (containing impurities) and the facets becomes more conspicuous. At this temperature, after maintaining for a certain period of time, under driving of the facets, the CNT network tightly adheres to the surface of copper. The facets continuously dissolve impurities (including catalyst particles, amorphous carbon, defects, and weak CNTs) in the original film tightly adhered to the facets (these impurities alloy, diffuse, or form solid solutions with the facets, i.e., dissolve), removing most or even all of the impurities. Simultaneously, as the facets grow up, the CNTs in the original network structure film move and approach each other under driving of the facets, starting a conspicuous reorganization process. Most of the CNTs in the network structure move to the grooves between the facets and the depressions formed at the edges of the facets. As the facets continue to grow close to 200 nm, the CNTs on them undergo more noticeable movement and mutual proximity. Since the original CNT network is a continuous porous structure, some CNTs align closely along the grooves and depressions of the facets, forming long common segments, and can cross the facets to tightly contact other CNTs, thereby changing the original network structure and reorganizing it into a new large-area Y-type interconnected network with a long common segment, basically completing the reorganization of the original CNT film network. Subsequently, when the heating temperature reaches T₃=1030° C., due to the near melting point of copper, the pre-melting of the surface of copper becomes more evident, and the morphological features of the facets basically disappear, while the pore structure already formed in the new CNT network will be preserved, completing the reorganization process. The shape of the new large-area Y-type interconnected network with a long common segment is basically maintained, the pores are uniform, with a size ranging from approximately 1 μm to 2 μm, and during the disappearance of the facets, almost all or all impurities are removed, resulting in a clean, free-standing large-area RCNT network film on the surface of the substrate, further reducing the film's areal density. Thus, under the dual action of reorganization caused by driving of the facets and constraint from the original network, RCNT-TCF/copper foil is obtained.

(6) Continuing holding at T₃=1030° C. for 20 minutes while introducing 2 sccm methane and 40 sccm hydrogen to grow graphene.

A heating procedure involves heating at a rate of 1-10° C./min to T₃=1030° C. and holding at T₂=900° C. for 30-90 minutes to allow sufficient time for the growth of the facets.

(7) Once the heating process is complete, cooling the G-RCNT TCF/copper foil to room temperature quickly and then removing it from the growth chamber.

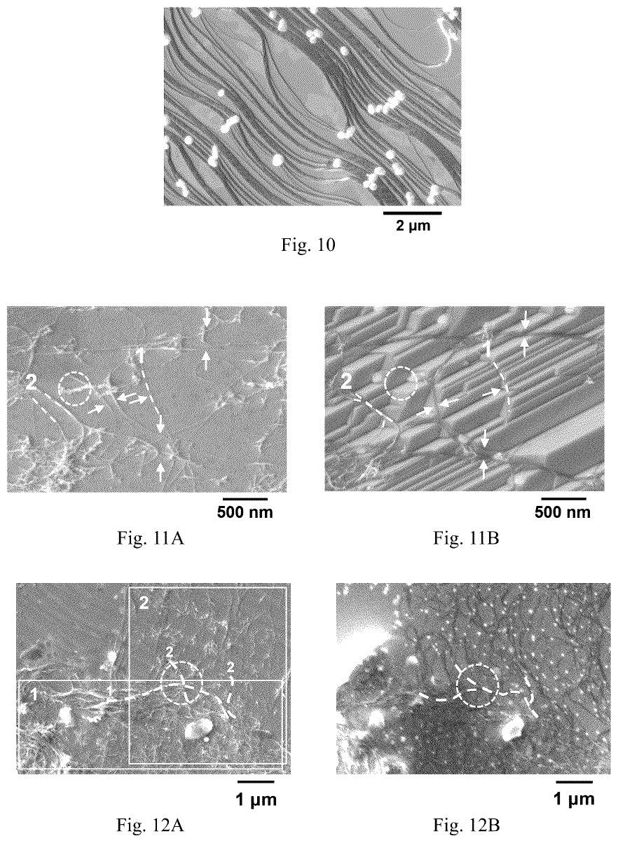

FIG. 10 shows the SEM image of the copper facets according to this embodiment, in which the copper facets obtained by heating copper at a rate of 10° C./min to 1030° C. under an oxygen partial pressure of 10⁻¹ Torr followed by rapid cooling.

(8) Floating the G-RCNT TCF/copper foil in ammonium persulfate solution to etch off the copper foil, obtaining a G-RCNT TCF floating on the 3surface of the ammonium persulfate solution. Finally, rinsing with deionized water to obtain a free-standing G-RCNT TCF on the surface of deionized water. Transferring the free-standing G-RCNT TCF onto a substrate for performance testing.

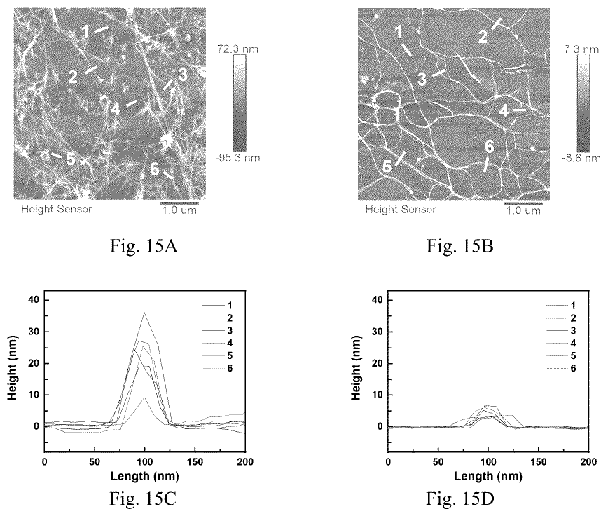

FIG. 14A shows the SEM image of the original CNT film, and FIG. 14B shows the SEM image of the G-RCNT TCF. From FIG. 14A, it manifests that the original CNT network exhibits a pore size of about 500 nm-1 μm, and there are X-type and Y-type connections between CNTs or CNT bundles, with some impurities on the network. In contrast, in FIG. 14B, the reorganized CNT network in the G-RCNT TCF has a pore size of about 1-2 μm, larger pores, longer bundle lengths between nodes, and primarily Y-type connections between CNTs with a long common segment, with less impurities visible on the network. AFM images of the original CNT film and the reorganized G-RCNT TCF are shown in FIGS. 15A and 15B, respectively. FIGS. 15C and 15D are the cross-sectional analysis views of the AFM images of the original CNT film and the G-RCNT TCF. In FIG. 15A, the surface height map of the original CNT film shows a root-mean-square roughness of 21.4 nm, and the typical AFM cross-sectional analysis data in FIG. 15C indicates that the height of the CNT bundles is approximately 6-40 nm, which includes the diameter of the bundles themselves plus the loose stacking distance in the height direction. In contrast, in FIG. 15B, the AFM surface height map of the G-RCNT TCF shows a root-mean-square roughness of only 2.26 nm, about 10 times smaller than the original CNT film. The typical AFM cross-sectional analysis data in FIG. 15D manifests that the height of the G-CNT network is less than 10 nm, with tight connections between bundles. The result indicates that the surface of the G-RCNT TCF is very flat. FIG. 16 shows the transparent conductive test results of various TCFs according to one embodiment of the preparation method of TCF of the present invention, demonstrating the significant synergistic improvement in transmittance (86%) and conductivity (sheet resistance 69 Ω/sq) of the reorganized G-CNT TCF compared to the original CNT film. Its figure of merit (35.0) is 4.6 times higher than that of the original CNT film.

To provide a comparison with Embodiment 1, a traditional method was used to prepare G-CNT TCF, as follows:

### Embodiment 2: Preparation Method of G-CNT TCF

In order to further exemplify the enhancement effect of the facets on the physical properties of the film, and to rule out the possibility that the substrate optimizes the film structure without driving of the facets under high temperature, a comparative Embodiment 2 is proposed as follows:

(1) Using the CVD method to grow a single-walled CNT film.

(2) Performing electrochemically polishing on a copper foil to make its surface smooth.

(3) Laying the CNT film (transmittance 81%, sheet resistance 163 Ω/sq, figure of merit 10) flat on the surface of the copper foil. Preferably, adding a few drops of ethanol to wet the CNT film/copper foil interface for better contact.

(4) After the organic solvent evaporates, placing the CNT film/copper foil into a growth chamber of a heating furnace. Evacuating air from the growth chamber, then introducing hydrogen into the growth chamber at a flow rate of 40 sccm throughout the process, providing a reducing environment in the growth chamber.

(5) Setting up the same heating program as described in Embodiment 1, heating the CNT film/copper foil in a reductive environment. Under the protection of hydrogen (flow rate of 40 sccm), when the heating temperature Tₓ>T₁=700° C., no facets appear on the surface of the copper foil. When the heating temperature reaches T₂=900° C. and is maintained for 30-90 minutes, facets still do not appear, and the CNT network remains suspended on the surface of the copper foil without tightly adhering of impurities to the surface of the copper foil. The movement of CNTs is minimal or nonexistent. As the temperature increases, there is still no facet observed, and there is no conspicuous change in the CNT network. Subsequently, when the heating temperature reaches T₃=1030° C., facets never appear, and the heating process is completed.

(6) Continuing holding at T₃=1030° C. for 20 minutes while introducing 2 sccm methane and 40 sccm hydrogen to grow graphene.

The heating program involves heating at a rate of 1-10° C./min to T₃=1030° C., with a hold time of 30-90 minutes at T₂=900° C. to allow enough time for the growth of the facets.

(7) Once the heating process is complete, cooling the G-CNT TCF/copper foil to room temperature quickly and then removing them from the growth chamber.

(8) Floating the G-CNT TCF/copper foil in ammonium persulfate solution to etch off the copper foil, obtaining a G-CNT TCF floating on the surface of the ammonium persulfate solution. Finally, rinsing with deionized water to obtain a G-CNT TCF floating on the surface of deionized water. Transferring the G-CNT TCF onto a suitable substrate for performance testing.

The SEM image of the G-CNT TCF is shown in FIG. 17. As shown in FIG. 17, it demonstrates that compared to the original CNT network film, the network structure of the resultant G-CNT TCF has not been optimized significantly, lacking formation of a large-area Y-type connection with a long common segment, remaining rough with many impurities on the resultant film.

### Embodiment 3: Large-Area Reorganized CNT Film Preparation Method

(1) Step (1) in this embodiment is the same as that described in Step (1) of Embodiment 1 and will not be elaborated here.

(2) Taking a large copper foil with an area of 220 mm×310 mm and performing electrochemical polishing to make its surface flat.

(3) Laying 12 pieces of CNT films on the surface of copper foil through splicing, to form two layers of CNT films covering the entire surface of copper foil. In detail, each piece of a free-standing single-walled CNT film has an area of 50 mm×210 mm with an areal density ≤2 μg/cm². From the top view, there are no gaps between the CNT films to expose the copper foil, and the upper and lower layers are stacked together with uniform thickness to ensure the overall surface is intact and flat. Preferably, adding a few drops of ethanol to wet the CNT film/copper foil interface for better contact.

(4) After the organic solvent evaporates, placing the large-area CNT film/copper foil into a growth chamber of a heating furnace. Using argon gas for purging the growth chamber to make the oxygen partial pressure in the growth chamber less than 10⁻¹ Torr.

(5) Setting up a heating program to heat the large-area CNT film/copper foil. When the heating temperature exceeds T₁=700° C., obvious facets appear on the copper foil surface; as the temperature continues to rise, the facets grow up gradually. When the heating temperature reaches T₂=900° C., the step width of the facets approaches 100 nm. The interaction between CNTs and the facets becomes conspicuous, causing the CNT network to adhere tightly to the surface of copper. Some impurities begin to dissolve, and as the facets grow up, the CNTs start to move, initiating the reorganization process. As the temperature increases, the facets continue to grow, and the CNTs exhibit more noticeable movement and alignment. Under driving of the facets, due to the original porous structure of the CNT network, some CNTs closely contact along the grooves and depressions of the facets, forming long common segments, and can cross the facets to tightly connect with other CNTs. Through continuous interaction between the facets and the original network film, CNT networks from different layers adhere tightly to the surface of copper, undergoing reorganization caused by driving of the facets that can change the original network structure. This reorganization forms a new large-area Y-type interconnected network with a long common segment, essentially completing the reorganization of the original CNT film network. Subsequently, when the heating temperature reaches T₃=1030° C., nearing the melting point of copper, the pre-melting of the surface of copper becomes more apparent, and the morphological features of the facets disappear. The reorganization process is completed, preserving the shape of the new large-area Y-type interconnected network with a long common segment. During the disappearance of the facets, almost all or all impurities are removed, resulting in a clean, large-area RCNT network film on the surface of the substrate, further reducing the film's areal density. Thus, under the dual effects of reorganization under driving of the facets and constraint from the original network, a large-area reorganized CNT film/copper foil is obtained.

The heating program involves heating at a rate of 1-10° C./min to 1030° C., with a holding period of 30-90 minutes at 900° C. to allow sufficient time for growth of facets.

(6) Once the heating process is complete, cooling the large-area RCNT-TCF/copper foil to room temperature quickly and then fetching them from the growth chamber.

(7) Floating the large-area RCNT-TCF/copper foil on an ammonium persulfate solution to etch off the copper foil, resulting in a large-area RCNT-TCF floating on the surface of the ammonium persulfate solution. Finally, rinsing with deionized water to obtain a free-standing large-area RCNT-TCF on the surface of deionized water. Transferring the free-standing G-RCNT TCF to a target substrate for further application.

The free-standing large-area RCNT-TCF is directly retrieved from the rinsing liquid surface, with a free-standing area exceeding 15 cm×15 cm and an areal density≤2 μg/cm².

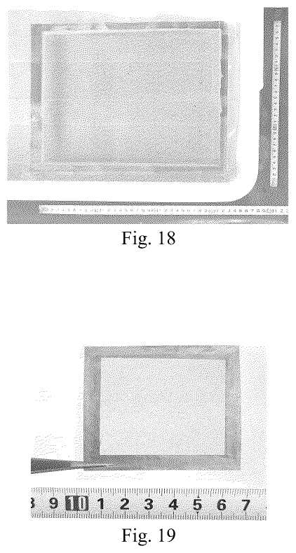

FIG. 18 shows the free-standing large-area RCNT-TCF floating on the surface of deionized water, with an area equivalent to A4 paper size (approximately 21 cm×30 cm) and an areal density≤2 μg/cm².

### Embodiment 4: Large-Area Reorganized G-CNT TCF Preparation Method

Steps (1)-(5) in this embodiment are identical to Steps (1)-(5) in Embodiment 3 and are not repeated here.

(6) Continuing holding at 1030° C. for 20 minutes while introducing 2 sccm methane and 40 sccm hydrogen to grow graphene.

The heating program involves heating at a rate of 1-10° C./min to 1030° C., with a holding period of 30-90 minutes at 900° C. to allow sufficient time for growth of facets.

(7) Once the heating process is complete, cooling the large-area G-RCNT TCF/copper foil to room temperature quickly and then fetching them from the growth chamber.

(8) Floating the large-area G-RCNT TCF/copper foil on an ammonium persulfate solution to etch off the copper foil, resulting in a large-area G-RCNT TCF floating on the surface of the ammonium persulfate solution. Finally, rinsing with deionized water to obtain a free-standing large-area G-RCNT TCF.

The free-standing large-area G-RCNT TCF is shown in FIG. 14. FIGS. 14A and 14B illustrate the SEM images of the original CNT film and the G-RCNT TCF, respectively. Consequently, the free-standing large-area G-RCNT TCF floating on the surface of deionized water, with an area equivalent to A4 paper size, exhibits transmittance greater than 85% and excellent uniformity.

The free-standing large-area G-RCNT TCF is directly retrieved from the rinsing liquid surface, with an area exceeding 20 cm².

A free-standing large-area G-RCNT TCF in air is shown in FIG. 19, with an area of >5 cm×4 cm and a visible transmittance of about 90%. The results manifest that the free-standing large-area G-RCNT TCF in air exhibits a high transmittance more than 85% and excellent uniformity.

### Embodiment 5: Large-Area Reorganized G-CNT TCF Preparation Method

(1) Growing single-walled CNT films by CVD method.

(2) Taking a large copper foil with an area of 310 mm×440 mm, and performing high-temperature annealing to make its surface flat.

(3) Laying 24 pieces of free-standing CNT films on the surface of copper foil through splicing, to form two layers of CNT films covering the entire surface of copper foil. Each piece of free-standing CNT film has an area of 50 mm×210 mm. From the top view, there are no gaps between the CNT films to expose the copper foil; and the upper and lower layers are stacked together with uniform thickness to ensure the overall surface is intact and flat. Preferably, add a few drops of ethanol to wet the CNT film/copper foil interface for better contact.

(4) After the organic solvent evaporates, place the large-area CNT film/copper foil into a heating furnace. Using argon gas for purging the growth chamber to reduce the oxygen partial pressure in the growth chamber to 10⁻¹ Torr.

(5) Same as Step (5) in Embodiment 3.

(6) Same as Step (6) in Embodiment 4.

The heating program involves heating at a rate of 1-10° C./min to T₃=1030° C., with a holding period of 30-90 minutes at T₂=900° C. to allow sufficient time for facet growth.

(7) and (8), same as Steps (7) and (8) in Embodiment 4.

A free-standing large-area G-RCNT TCF is shown in FIG. 20. FIG. 20 illustrates a free-standing large-area G-RCNT TCF floating on the surface of the substrate etchant solution according to one embodiment of the invention. The image in FIG. 20 shows a free-standing large-area G-RCNT TCF floating on the surface of the substrate etchant solution, with an area equivalent to A3 paper size (approximately 30 cm×42 cm). From FIG. 20, it can be seen that the free-standing large-area G-RCNT TCF floats on the surface of the substrate etchant solution, with A3 paper size, exhibits transmittance greater than 85% and excellent uniformity.

### Embodiment 6: Large-Area Reorganized G-CNT TCF Preparation Method

(1) Growing free-standing single-walled CNT films by CVD method.

(2) Taking a large copper foil with an area of 120 mm×1100 mm, and performing high-temperature annealing to make its surface flat.

(3) Laying 20 pieces of free-standing CNT films on the surface of copper foil through splicing, to form two layers of CNT films covering the entire surface of copper foil. Each piece of free-standing CNT film has an area of 50 mm×210 mm and an areal density≤2 μg/cm². From the top view, there are no gaps between the CNT films to expose the copper foil, and the upper and lower layers are stacked together with uniform thickness to ensure the overall surface is intact and flat. Preferably, adding a few drops of ethanol to wet the CNT film/copper foil interface for better contact.

Steps (4)-(8) in this embodiment are the same as Steps (4)-(8) in Embodiment 5.

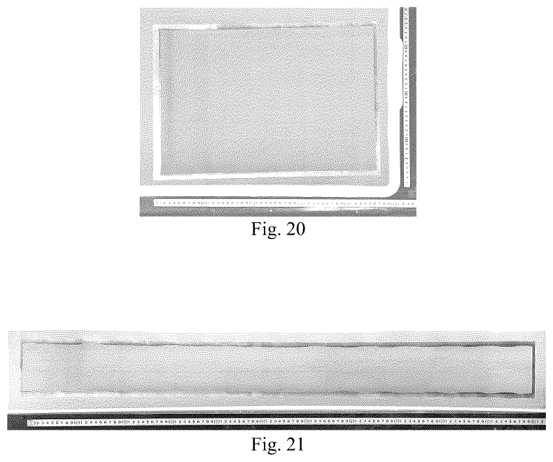

The free-standing large-area G-RCNT TCF is shown in FIG. 21, floating on the surface of deionized water, with an area of 1 m×10 cm, and exhibits excellent transmittance and uniformity.

### Embodiment 7: Reorganized G-CNT TCF Preparation Method

(1) Growing CNTs using the vapor-phase pyrolysis method.

(2) Performing electrochemical polishing on a nickel foil to make its surface flat.

(3) Using a carrier gas containing CNTs to uniformly sweep the surface of nickel foil to form a CNT film. Preferably, adding a few drops of acetone to wet a CNT film/nickel foil interface for better contact.

(4) After the organic solvent evaporates, placing the CNT film/nickel foil into a growth chamber of a heating furnace. Using argon gas for purging the growth chamber to reduce the oxygen partial pressure in the growth chamber to less than 1 Torr. Setting up a heating program and heating the CNT film/nickel foil. When the heating temperature exceeds T₁=800° C., obvious facets appear on the surface of nickel foil; as the temperature continues to rise, the facets begin to grow gradually. When the heating temperature reaches T₂=1000° C., the step width of the facets approaches 100 nm. The interaction between CNTs and the facets becomes conspicuous, causing the CNT network to adhere tightly to the nickel surface. Some impurities begin to dissolve, and as the facets grow up, the CNTs start to move, initiating the reorganization process. As the temperature increases, the facets continue to grow, and the CNTs exhibit more noticeable movement and alignment under driving of the facets. Various impurities are completely removed. Subsequently, when the heating temperature reaches T₃=1100° C., nearing the melting point of nickel, the pre-melting of the surface of nickel foil becomes more apparent, and the morphological features of the facets disappear. The reorganization process is completed, yielding a large-area RCNT-TCF/nickel foil.

(5) Continuing holding at T₃=1100° C. for 20 minutes while introducing 2 sccm methane and 40 sccm hydrogen to grow graphene.

The heating program involves heating at a rate of 10-100° C./min to T₃=1100° C., with a holding period of 3-50 minutes at T₂=1000° C. to allow sufficient time for growth of the facets.

(6) Once the heating process is complete, cooling the G-RCNT TCF/nickel foil to room temperature quickly and then fetching them from the growth chamber.

(7) Floating the G-RCNT TCF/nickel foil on an ammonium persulfate solution to etch off the nickel foil, resulting in a large-area G-RCNT TCF floating on the surface of the ammonium persulfate solution. Finally, rinsing with deionized water to obtain a large-area free-standing G-RCNT TCF floating on deionized water.

Alternatively, (5) cooling the RCNT-TCF/nickel foil to room temperature quickly and then fetching them from the growth chamber.

(6) Floating the RCNT-TCF/nickel foil on an ammonium persulfate solution to etch off the nickel foil, resulting in a large-area RCNT-TCF floating on the surface of the ammonium persulfate solution. Finally, rinsing with deionized water to obtain a large-area free-standing RCNT-TCF floating on deionized water.

### Embodiment 8: Reorganized G-CNT TCF Preparation Method

(1) Preparing single-walled CNTs using the arc discharge method.

(2) Performing electrochemical polishing on a platinum foil to make its surface flat.

(3) Depositing CNTs on a surface of a platinum foil uniformly. Preferably, adding a few drops of ethanol to wet the CNT film/platinum foil interface for better contact.

(4) After the organic solvent evaporates, placing the CNT film/platinum foil into a growth chamber of a heating furnace. Using argon gas for purging the growth chamber to make the oxygen partial pressure in the growth chamber less than 1 Torr.

(5) Setting up a heating program and heating the CNT film/platinum foil. When the heating temperature exceeds T₁=1000° C., obvious facets appear on the surface of platinum foil; as the temperature continues to rise, the facets grow up gradually. When the heating temperature reaches T₂=1100° C., the step width of the facets approaches 100 nm. The interaction between CNTs and the facets becomes conspicuous, causing the CNT network to adhere tightly to the platinum surface. Some impurities begin to dissolve, and as the facets grow up, the CNTs start to move, initiating the reorganization process. As the temperature increases, the facets continue to grow up, and the CNTs exhibit more noticeable movement and alignment under driving of the facets. Subsequently, when the heating temperature reaches T₃=1300° C., nearing the melting point of platinum, the pre-melting of the surface of platinum foil becomes more apparent, and the morphological features of the facets disappear. The reorganization process is completed.

(6) Continuing holding at 1300° C. while introducing 1 sccm methane and 40 sccm hydrogen to grow graphene.

The heating program involves heating at a rate of 10-100° C./min to T₃=1300° C., with a holding period of more than 30 minutes at T₂=1100° C. to allow sufficient time for growth of the facets.

(7) Once the heating process is complete, cooling the G-RCNT TCF/platinum foil to room temperature quickly and then fetching them from the growth chamber.

(8) Floating the G-RCNT TCF/platinum foil on a hydrochloric acid-hydrogen peroxide mixed solution to etch off the platinum foil, resulting in a large-area G-RCNT TCF floating on the surface of hydrochloric acid-hydrogen peroxide mixed solution. Finally, rinsing with deionized water to obtain a free-standing G-RCNT TCF floating on the surface of deionized water.

By this point, those skilled in the art should recognize that although multiple exemplary embodiments of the present invention have been shown and described in detail herein, many other variations or modifications may be determined or derived directly from the content disclosed herein without departing from the spirit and scope of the present invention. Therefore, the scope of the present invention should be understood and considered as covering all such other variations or modifications.

What is claimed is:

1. A method for preparing a transparent conductive film (TCF), comprising:
laying an original carbon nanotube (CNT) film with a predetermined area on a surface of a substrate and placing them into a growth chamber;
enabling the substrate to undergo surface reconstruction with a gas in the growth chamber, accompanied by transport of atoms constituting facets, to form said facets, the facets being manifested as a regular stepped or zigzag pattern at a mesoscopic scale on the surface of the substrate; and
making the facets interact with the original CNT film, to remove impurities from the original CNT film, and to cause at least a portion of CNTs in the original CNT film to move under driving of the facets, thereby compelling adjacent CNTs or bundles to adhere closely together, resulting in reorganization of a CNT network in the original CNT film to form a whole reorganized CNT transparent conductive film (RCNT-TCF).

2. The method for preparing a TCF according to claim 1,
wherein a step of enabling the substrate to undergo surface reconstruction with a gas in the growth chamber to form the facets includes:
purging the growth chamber to control a partial pressure of the gas in the growth chamber that interacts with the substrate to initiate the surface reconstruction to be within a set range; and
heating the growth chamber to control the surface reconstruction that occurs under interactions of the gas and the substrate, thereby forming the facets.

3. The method for preparing a TCF according to claim 2,
wherein the gas is a gas, in the growth chamber, that is capable of interacting with the substrate to initiate surface reconstruction, and includes any one or a mixture of oxidizing gases, or any one or a mixture of reducing gases;
a source of the gas includes any one of forms of gas, liquid, and solid, or any combination of the above multiple forms.

4. The method for preparing a TCF according to claim 3,
wherein making the facets interact with the original CNT film includes:
continuing heating the growth chamber to promote gradual growth of the facets on the substrate, thereby facilitating gradual tight adhesion of the CNT network to the facets and gradual elimination of impurities in the original CNT film; and
the CNTs in the original CNT network moving and approaching each other as the facets grow up, leading to their reorganization into a Y-type interconnected network with a long common segment to form a new reorganized CNT network, thereby obtaining the RCNT-TCF.

5. The method for preparing a TCF according to claim 1,
wherein after making the facets interact with the original CNT film, the method further comprises: introducing a carbon source and an auxiliary gas into the growth chamber to grow graphene, thereby obtaining a hybrid graphene-reorganized CNT transparent conductive film (G-RCNT TCF).

6. The method for preparing a TCF according to claim 1,
wherein after making the facets interact with the original CNT film, the method further comprises:
cooling the RCNT-TCF at a preset cooling rate; and
etching the substrate off the cooled RCNT-TCF using a substrate etchant, allowing the RCNT-TCF to float on a surface of the substrate etchant, and washing the RCNT-TCF with a rinsing solution.

7. The method for preparing a TCF according to claim 5,
wherein after introducing a carbon source and an auxiliary gas into the growth chamber to grow graphene, the method further comprises:
cooling the G-RCNT TCF at a preset cooling rate; and
etching the substrate off the cooled G-RCNT TCF using a substrate etchant, allowing the G-RCNT TCF to float on a surface of the substrate etchant, and washing the G-RCNT TCF with a rinsing solution.

8. The method for preparing a TCF according to claim 1,
wherein laying the original CNT film with a predetermined area on the surface of the substrate includes:
splicing multiple pieces of the original CNT films and laying them on the surface of the substrate to ensure the surface of the substrate is completely bespread with the original CNT films, with at least one layer of the original CNT films covering the surface of the substrate.

9. The method for preparing a TCF according to claim 8,
wherein after laying the original CNT film with a predetermined area on the surface of the substrate, the method further comprises:
dripping a volatile organic solvent onto the original CNT film to infiltrate the original CNT film to increase contact between the original CNT film and the surface of the substrate; and
after the organic solvent is completely evaporated, placing the original CNT film on the substrate into the growth chamber.

10. The method for preparing a TCF according to claim 1,
wherein the CNTs in the original CNT film include at least one type or a combination of multiple types of the following: single-walled CNTs, double-walled CNTs, few-walled CNTs, and multi-walled CNTs.

11. The method for preparing a TCF according to claim 1,
wherein a thickness of the original CNT film is greater than 0.1 nm.
